(19) United States
(12) Patent Application Publication
(10) Pub. No.: US 2022/0416124 A1
(43) Pub. Date: Dec. 29, 2022

(54) INORGANIC LIGHT-EMITTING ELEMENT AND SEMICONDUCTOR DEVICE INCLUDING INORGANIC LIGHT-EMITTING ELEMENT

(71) Applicant: Semiconductor Energy Laboratory Co., Ltd., Atsugi-shi, Kanagawa-ken (JP)

(72) Inventors: Kazuki TANEMURA, Isehara (JP); Haruyuki BABA, Isehara (JP); Takahiro FUKUTOME, Atsugi (JP)

(21) Appl. No.: 17/779,697

(22) PCT Filed: Dec. 7, 2020
(86) PCT No.: PCT/IB2020/061571

§ 371 Date: May 25, 2022

(30) Foreign Application Priority Data
Dec. 20, 2019 (JP) 2019-230371

(51) Int. Cl. H01L 33/26; H01L 27/15; H01L 49/02; H01L 29/24; H01L 29/786; H01L 33/60; H01L 33/00

(52) U.S. Cl. CPC H01L 33/26; H01L 27/15; H01L 28/60; H01L 29/24; H01L 29/78648; H01L 29/7869; H01L 33/60; H01L 33/005

(57) ABSTRACT

A semiconductor device including an inorganic light-emitting element is provided. The semiconductor device includes the inorganic light-emitting element, a transistor, and a capacitor. The inorganic light-emitting element includes a first film and a second film. The first film contains indium, oxygen, and nitrogen, and the second film contains gallium and nitrogen. The first film has a wurtzite structure or a cubic crystal structure, and the second film has a wurtzite structure and grows on the first film. The first film functions as a cathode electrode of the inorganic light-emitting element. One electrode of the capacitor is formed above the second film included in the inorganic light-emitting element, and the transistor including a metal oxide in a semiconductor layer is formed above the other electrode of the capacitor. The one electrode of the capacitor has a function of reflecting light emitted from the inorganic light-emitting element. The inorganic light-emitting element emits light through the first film.

### TECHNICAL FIELD

One embodiment of the present invention relates to a semiconductor device including a metal nitride film and a metal nitride film formed over a metal oxynitride film. Another embodiment of the present invention relates to an inorganic light-emitting element, a lighting device, a display device, an electronic device, and a semiconductor device that include the metal nitride film.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an imaging device, a communication device, an electronic device, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

A nitride semiconductor containing a Group 13 element (e.g., gallium) is known as a constituent material of an inorganic light-emitting element, a power semiconductor element, or a communication device. Patent Document 1 discloses a manufacturing method of a nitride semiconductor.

A metal oxynitride, which includes metal, oxygen, and nitrogen, is known as a pigment or a photocatalyst material. In addition, a metal oxynitride has attracted attention as a semiconductor material or an insulating material used for a semiconductor device or the like. Patent Document 2 discloses a semiconductor material including a metal oxynitride containing indium, gallium, and zinc.

As one of methods for forming an in-plane oriented thin film (also referred to as a single crystal thin film), an epitaxial growth method is known. Here, in-plane orientation refers to the regularity of crystal orientation in a horizontal direction with respect to a substrate. Patent Document 3 discloses a method for forming a single crystal InGaO₃(ZnO)₅ thin film by a reactive solid-phase epitaxial method.

### REFERENCE

### Patent Document

[Patent Document 1] International Publication No. WO2005/6420
[Patent Document 2] Japanese Published Patent Application No. 2015-18929
[Patent Document 3] Japanese Published Patent Application No. 2004-103957

### SUMMARY OF THE INVENTION

### Problems to be Solved by the Invention

In the manufacturing method of a nitride semiconductor disclosed in Patent Document 1, the nitride semiconductor is formed by a pulsed laser deposition (PLD) method. The PLD method is a deposition method utilizing laser ablation and needs a laser and an optical system. In addition, there is a problem in that the deposition rate of a thin film largely differs between the front of plasma (plume) induced in a target by laser irradiation and the other part. It is thus difficult to form a lot of thin films by the PLD method.

The state of the metal oxynitride disclosed in Patent Document 2 is an amorphous state where an interatomic bond is disordered. The metal oxynitride in an amorphous state has a void or a low-density region, and therefore, the stability of the metal oxynitride might be low. Accordingly, it is preferable that a metal oxynitride used for a semiconductor device or the like have high crystallinity. It is particularly preferable that the metal oxynitride have in-plane orientation.

The reactive solid-phase epitaxy method disclosed in Patent Document 3 has a problem in that high-temperature treatment is required; for example, treatment for heating a substrate to 1000° C. or higher is performed before deposition of an InGaO₃(ZnO)₅ thin film, and heat diffusion treatment is performed at 1300° C. or higher after the deposition of the thin film. Furthermore, to form a single crystal InGaO₃(ZnO)₅ thin film, an epitaxially grown ZnO thin film needs to be provided on the substrate. In this manner, there are various limitations on formation of an epitaxially grown thin film by a conventional technique. Note that in this specification, a high temperature refers to a temperature of 700° C. or higher, and a low temperature refers to a temperature of 600° C. or lower, for example.

Thus, an object of one embodiment of the present invention is to provide an inorganic light-emitting element or the like including a metal nitride film deposited by epitaxial growth on a metal oxynitride film. Another object of one embodiment of the present invention is to increase the productivity of an inorganic light-emitting element or the like including a metal nitride film. Another object of one embodiment of the present invention is to provide a method for depositing a metal oxynitride film by epitaxial growth at a low temperature. Another object of one embodiment of the present invention is to provide a method for depositing a metal oxynitride film by epitaxial growth without high-temperature treatment before and after the deposition of the metal oxynitride film. Another object of one embodiment of the present invention is to provide a method for depositing a metal nitride film by epitaxial growth on a metal oxynitride film without high-temperature treatment.

Note that the description of these objects does not preclude the existence of other objects. One embodiment of the present invention does not have to achieve all these objects. Other objects are apparent from the description of the specification, the drawings, the claims, and the like, and other objects can be derived from the description of the specification, the drawings, the claims, and the like.

### Means for Solving the Problems

An inorganic light-emitting element of one embodiment of the present invention includes a first film (a metal oxynitride film) and a second film (a metal nitride film). The first film contains indium and oxygen and the second film contains gallium and nitrogen. The second film has a wurtzite structure. The first film can function as a cathode electrode of the inorganic light-emitting element. Note that the first film preferably further contains gallium, zinc, and nitrogen.

A semiconductor device of another embodiment of the present invention includes an inorganic light-emitting element, a transistor, and a capacitor. The inorganic light-emitting element includes a first film (a metal oxynitride film) and a second film (a metal nitride film). The first film contains indium and oxygen and the second film contains gallium and nitrogen. The second film has a wurtzite structure. One electrode of the capacitor is formed above the second film included in the inorganic light-emitting element, and the transistor is formed above the other electrode of the capacitor. The one electrode of the capacitor has a function of reflecting light emitted from the inorganic light-emitting element, and the inorganic light-emitting element can emit light through the first film. The transistor includes a metal oxide in a semiconductor layer and the semiconductor layer of the transistor preferably contains indium, gallium, zinc, and oxygen.

Another embodiment of the present invention is a manufacturing method of a first film. The first film can be epitaxially grown on a substrate by a sputtering method using an oxide target while a gas containing a nitrogen gas is introduced. Note that the first film is preferably an in-plane oriented film. The oxide target contains zinc and has conductivity. The substrate is at higher than or equal to 80° C. and lower than or equal to 500° C. during deposition of the first film, and the flow rate of the nitrogen gas is higher than or equal to 50% and lower than or equal to 100% of the total flow rate of the gas. Note that the oxide target preferably further contains indium and gallium.

In the above, it is preferable that the substrate be a single crystal yttria-stabilized zirconia (YSZ) substrate, and a plane orientation of the substrate be (111). Alternatively, it is preferable that the substrate be a single crystal a-plane sapphire substrate, and a plane orientation of the substrate be (110).

Another embodiment of the present invention is a manufacturing method of a second film. The second film can be epitaxially grown on a first film by a sputtering method using a nitride target while a gas containing a nitrogen gas is introduced. Note that the second film is preferably an in-plane oriented film. The nitride target contains gallium and nitrogen and has conductivity. The substrate is at higher than or equal to 80° C. and lower than or equal to 500° C. during deposition of the metal nitride film, and the flow rate of the nitrogen gas is higher than or equal to 80% and lower than or equal to 100% of the total flow rate of the gas.

In the above, it is preferable that diffraction peaks indicating six-fold symmetry be observed in ϕ scanning on the (101) plane of a crystal of the first film and the second film by an X-ray analysis. A smaller full width at half maximum (also referred to as Δϕ) in ϕ scanning by X-ray diffraction means better in-plane orientation.

### Effect of the Invention

According to one embodiment of the present invention, an inorganic light-emitting element or the like including a metal nitride film deposited by epitaxial growth on a metal oxynitride film can be provided. According to another embodiment of the present invention, the productivity of an inorganic light-emitting element or the like including a metal nitride film can be increased. According to another embodiment of the present invention, a method for depositing a metal oxynitride film by epitaxial growth at a low temperature can be provided. According to another embodiment of the present invention, a method for depositing a metal oxynitride film by epitaxial growth without high-temperature treatment before and after the deposition of the metal oxynitride film can be provided. According to another embodiment of the present invention, a method for depositing a metal nitride film by epitaxial growth on a metal oxynitride film without high-temperature treatment can be provided.

Note that the description of these effects does not preclude the existence of other effects. One embodiment of the present invention does not have to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a diagram showing a metal oxynitride film epitaxially grown on a substrate. FIG. 1B is a diagram showing a crystal plane of a crystal of the metal oxynitride film. FIG. 1C is a diagram showing atomic arrangement of the crystal.

FIG. 2 is a diagram showing a metal oxynitride film epitaxially grown on a substrate.

FIG. 3 is a diagram showing a range of the atomic ratio of metals contained in an oxide target.

FIG. 4 is a schematic diagram showing a sputtering apparatus.

FIG. 5 is an experiment arrangement diagram in X-ray measurement.

FIG. 6A to FIG. 6C are a pole figure and diagrams showing the intensity distribution obtained by pole measurement.

FIG. 7 is a diagram illustrating a structure example of an inorganic light-emitting element.

FIG. 8 is a diagram illustrating a structure example of a display device.

FIG. 9A and FIG. 9B are diagrams illustrating structure examples of a transistor.

FIG. 10A to FIG. 10C are diagrams illustrating structure examples of a transistor.

FIG. 11A to FIG. 11C are diagrams illustrating structure examples of a transistor.

FIG. 12 is a diagram illustrating a structure example of a display device.

FIG. 13A to FIG. 13C are diagrams illustrating structure examples of a display device.

FIG. 14 is a diagram illustrating a structure example of a display device.

FIG. 15A and FIG. 15B are diagrams illustrating a structure example of an electronic device.

FIG. 16A to FIG. 16E are diagrams illustrating structure examples of electronic devices.

FIG. 17 is a graph showing the X-ray analysis results of samples in Example.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of the embodiments below.

In the drawings, the size, the layer thickness, or the region is exaggerated for clarity in some cases. Therefore, they are not limited to the illustrated scale. Note that the drawings schematically illustrate ideal examples, and embodiments of the present invention are not limited to shapes, values, and the like shown in the drawings. For example, in an actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases.

In a top view (also referred to as a “plan view”), a perspective view, or the like, particularly, some components might not be illustrated for easy understanding of the invention. In addition, some hidden lines and the like might not be shown.

Furthermore, in this specification and the like, terms for describing arrangement, such as “over” and “below”, are used for convenience to describe the positional relationship between components with reference to drawings. Furthermore, the positional relationship between components is changed as appropriate in accordance with a direction in which the components are described. Thus, terms for the description are not limited to terms used in the specification, and description can be made appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or text, a connection relationship other than a connection relationship shown in drawings or text is regarded as being disclosed in the drawings or the text. Here, X and Y each denote an object (e.g., a device, an element, a circuit, a wiring, an electrode, a terminal, a conductive film, or a layer).

In this specification and the like, a transistor is an element having at least three terminals of a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

Furthermore, functions of a source and a drain might be interchanged with each other when a transistor of opposite polarity is employed or when the direction of current is changed in circuit operation, for example. Therefore, the terms “source” and “drain” can sometimes be interchanged with each other in this specification and the like.

In this specification and the like, the term “insulator” can be replaced with an insulating film. Furthermore, the term “conductor” can be replaced with a conductive film. Moreover, the term “semiconductor” can be replaced with a semiconductor film or a semiconductor layer.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. In addition, the term “substantially parallel” indicates a state where two straight lines are placed at an angle greater than or equal to −30° and less than or equal to 30°. Furthermore, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification, a crystal plane is represented by Miller indices. Miller indices are expressed by three integers in parentheses. The direction of crystal plane alignment (a direction perpendicular to the crystal plane) is referred to as a crystal orientation. The crystal orientation is expressed by three integers in square brackets. For example, a crystal plane is expressed as (111), and a crystal orientation is expressed as [111]. Note that in the case of a hexagonal system, a notation called Miller-Bravais indices may be used. Specifically, plane indices of a hexagonal crystal lattice are represented, using four integers (h, k, i, and l), as (hkil). Here, i=−(h+k). The index i can be calculated from the values of the index h and the index k; therefore, in this specification, a crystal plane of a hexagonal system is also represented by a notation using three integers, Miller indices (hkl). In the crystallography, a bar is placed over a number in the expression of crystal planes, orientations, and space groups; however, in this specification and the like, because of application format limitations, crystal planes, orientations, and space groups are sometimes expressed by placing a minus sign (−) before a number instead of placing a bar over the number.

In this specification, a crystal plane that appears at a surface of a single crystal substrate may be referred to as a plane orientation of the single crystal substrate.

In this specification, a lattice point in a reciprocal lattice (also referred to as a reciprocal lattice point), which corresponds to a crystal plane, is represented by indices without parentheses.

### Embodiment 1

In this embodiment, a method for manufacturing a metal nitride film used for an inorganic light-emitting element of one embodiment of the present invention will be described.

A metal nitride, which includes metal and nitrogen, has attracted attention as a semiconductor material or an insulating material used in a semiconductor device. It is preferable that a metal nitride used in a semiconductor device have a small amount of impurities or defects and high stability. Note that the small amount of impurities or defects of the metal nitride can be referred to as high crystallinity of the metal nitride. The high stability of the metal nitride refers to, for example, a less tendency to react with a material in contact with the metal nitride, no change in the crystallinity of the metal nitride, and a less tendency to cause defects in the metal nitride, owing to heat or the like generated by operation of the semiconductor device. The use of the metal nitride with a small amount of impurities or defects and high stability in a semiconductor device can improve the reliability of the semiconductor device.

In one embodiment of the present invention, a metal oxynitride film can be provided as a buffer layer between a substrate and a metal nitride in order to manufacture a metal nitride film that has a small amount of impurities and defects and high crystallinity. In order to manufacture a metal nitride film with high crystallinity, a metal oxynitride film with a small amount of impurities and defects is preferably provided.

The impurities in the metal oxynitride refer to, for example, components other than main components that compose the metal oxynitride. For example, an element that is contained in the metal oxynitride at a concentration lower than 0.1 atomic % can be regarded as an impurity. Examples of the element include hydrogen, silicon, boron, phosphorus, carbon, and a transition metal except the main components composing the metal oxynitride. The defects in the metal oxynitride refer to lattice defects; examples of the lattice defects include a point defect such as an oxygen vacancy and a nitrogen vacancy, a line defect such as dislocation, and a plane defect such as a crystal grain boundary. In addition, a void defect such as a void, and the like are given as the defects in the metal oxynitride.

Examples of a thin film include an in-plane oriented thin film, an orientation thin film, a non-oriented thin film (polycrystalline thin film), and an amorphous thin film, in terms of crystallinity. An orientation thin film is a thin film in which at least one crystal axis of each crystal of the thin film is aligned in a particular direction. An in-plane oriented thin film is a thin film in which three crystal axes of each crystal of the thin film are aligned in particular directions.

A thin film of a metal oxynitride used in a semiconductor device or the like preferably has orientation, and is further preferably an in-plane oriented thin film of a metal oxynitride. The in-plane oriented thin film of a metal oxynitride has a small amount of impurities or defects and a dense structure. Thus, the use of the in-plane oriented thin film of a metal oxynitride in a semiconductor device or the like can improve the reliability of the semiconductor device or the like.

Epitaxial growth is known as a method for forming an in-plane oriented thin film. Epitaxial growth means that a crystal forming a thin film is grown on a single crystal substrate with a certain crystal orientation relationship. Note that growth of a crystal on a single crystal substrate using the same material as the substrate, in which the crystal has the same lattice constant as a crystal of the substrate, is called homoepitaxial growth. In addition, growth of a crystal on a single crystal substrate using a different material from the substrate or a material having a different lattice constant from a crystal of the substrate is called heteroepitaxial growth. The heteroepitaxial growth becomes possible when a material that has small lattice mismatch with respect to the crystal of the substrate is selected, or when a layer that relieves lattice distortion (also referred to as a buffer layer) is provided between the substrate and the thin film, for example.

A solid phase epitaxy (SPE) method, a liquid phase epitaxy (LPE) method, and a vapor phase epitaxy (VPE) method are given as the method of epitaxial growth.

The SPE method is a method in which a material deposited on a substrate surface is heated by electron beam irradiation or the like, so that the crystal structure of the material is changed into the same crystal structure as a crystal of the substrate. The LPE method is a method for separating a crystal part from a supersaturated solution onto a substrate surface. The VPE method is a method for depositing a component in a vapor phase onto a substrate surface. Examples of the VPE method include a pulsed laser deposition (PLD) method, an atomic layer deposition (ALD) method, and a molecular beam epitaxy (MBE) method. The MBE method is a method in which an element constituting a target crystal or a material containing the element is heated and evaporated in ultrahigh vacuum and a crystal is deposited on the heated substrate.

A conventional technique for epitaxial growth of a thin film has various conditions. Examples of the conditions are as follows: the thin film is deposited at a high temperature; the thin film is subjected to heat treatment at a high temperature (e.g., 1000° C. or higher) after being deposited; a substrate surface is subjected to planarization treatment before deposition of the thin film; one or more buffer layers are provided on the substrate; a substrate that has a similar lattice constant or thermal expansion is selected. As the planarization treatment on the substrate surface, heat treatment is performed on the substrate at a high temperature, for example.

In view of the above, in the method for manufacturing a metal oxynitride film of one embodiment of the present invention, the metal oxynitride film is epitaxially grown at a low temperature. In the manufacturing method, a metal oxynitride film is epitaxially grown on a single crystal substrate by a sputtering method with a gas introduced into a reaction chamber. According to one embodiment of the present invention, an in-plane oriented film can be formed by epitaxial growth.

The crystal structure of the metal oxynitride film that is to be epitaxially grown is preferably a hexagonal crystal structure. Among the hexagonal crystal structures, a wurtzite structure is particularly preferable. The wurtzite structure has a crystal orientation relationship that enables epitaxial growth with respect to a cubic crystal system (e.g., a diamond structure, a fluorite structure, or a zinc blende structure). For example, there is a crystal orientation relationship enabling epitaxial growth between [111] orientation of a cubic crystal and [001] orientation of a wurtzite structure. Accordingly, a metal oxynitride film that has a hexagonal crystal structure can be easily epitaxially grown on a single crystal substrate that has a crystal structure such as a cubic crystal structure or a hexagonal crystal structure. Furthermore, a material that has a crystal structure such as a cubic crystal structure or a hexagonal crystal structure can be easily epitaxially grown on the metal oxynitride film.

Note that other than the hexagonal crystal structure described above, a cubic crystal structure is preferable as the crystal structure of a metal oxide thin film that is to be epitaxially grown. Among the cubic crystal structures, a bixbyite (C-type rare earth) structure is preferable. The cubic crystal system has a crystal orientation relationship that enables epitaxial growth with respect to a hexagonal crystal system. As described above, [111] orientation of a cubic crystal and [001] orientation of a wurtzite structure have a crystal orientation relationship enabling epitaxial growth; thus, a metal nitride film having a hexagonal crystal structure can be easily epitaxially grown on the metal oxide thin film having the cubic crystal structure.

As the single crystal substrate, an insulator substrate such as a sapphire substrate or a stabilized zirconia substrate (e.g., an yttria-stabilized zirconia (YSZ) substrate) can be used. In the case where the crystal structure of the metal oxynitride is a wurtzite structure, a YSZ substrate with a (111) plane orientation or an a-plane sapphire substrate with a (110) plane orientation is preferably used as the substrate, for example. The use of the YSZ substrate or the a-plane sapphire substrate as the substrate facilitates formation of an in-plane oriented thin film of a metal oxynitride including a crystal with a wurtzite structure. Note that a substrate made of silicon, germanium, silicon carbide, gallium nitride, gallium arsenide, indium phosphide, zinc oxide, or the like may be used.

It is preferable that a difference in lattice constant (also referred to as lattice mismatch) between the crystal of the epitaxially grown thin film and the crystal of the substrate be small. The reduction in the lattice mismatch facilitates epitaxial growth of the thin film on the single crystal substrate.

One of methods for evaluating the degree of lattice mismatch is a lattice mismatch Aa, which is calculated by the following formula (1) with a lattice constant ae of the crystal of the epitaxially grown thin film and a lattice constant as of the crystal of the substrate.

$$\begin{matrix}[ Formula 1 ] & \\ Δ a = \frac{\vert {a}_{e} - {a}_{s} \vert}{{a}_{e}} & ( 1 )\end{matrix}$$

The lattice mismatch between the metal oxynitride film to be epitaxially grown and the single crystal substrate is preferably less than or equal to 15%, further preferably less than or equal to 10%. Thus, the metal oxynitride film can be easily epitaxially grown on the single crystal substrate.

Note that in the case where a metal oxynitride film including a crystal with a wurtzite structure is epitaxially grown on a single crystal substrate of a cubic system, for example, the crystal orientation of the substrate is [111] and the crystal orientation of the metal oxynitride film is [001]; therefore, the substrate and the metal oxynitride film have different crystal orientations. In that case, as is set to a value obtained by multiplying the lattice constant of the crystal of the substrate by the square root of two over two, whereby the lattice mismatch can be calculated. Specifically, in the case where a YSZ substrate with a lattice constant of approximately 0.51 nm in the a-axis direction is used as the single crystal substrate, the nearest neighbor interatomic distance is approximately 0.36 nm at the minimum when the YSZ substrate is seen from the [111] orientation. Therefore, in view of the above-described preferred range of the lattice mismatch, the lattice constant of the crystal of the metal oxynitride film in the a-axis direction is preferably greater than or equal to 0.31 nm and less than or equal to 0.41 nm, further preferably greater than or equal to 0.32 nm and less than or equal to 0.40 nm.

Furthermore, in the method for manufacturing a metal nitride film of one embodiment of the present invention, the metal nitride film is epitaxially grown on a metal oxynitride film or a metal oxide film at a low temperature. For example, in the case where a metal nitride film is epitaxially grown on a metal oxynitride film at a low temperature, the metal nitride film is epitaxially grown on the aforementioned metal oxynitride film by a sputtering method with a gas introduced into a reaction chamber. According to one embodiment of the present invention, an in-plane oriented film can be formed by epitaxial growth.

The crystal structure of the metal nitride film that is to be epitaxially grown is preferably a hexagonal crystal structure. Among the hexagonal crystal structures, a wurtzite structure is particularly preferable. Since the metal oxynitride film that has been epitaxially grown has a wurtzite structure, a metal nitride film having a wurtzite structure is easily grown on the metal oxynitride film.

For example, a metal nitride film epitaxially grown on a metal oxynitride film epitaxially grown on a YSZ substrate with a (111) plane orientation or an a-plane sapphire substrate with a (110) plane orientation has higher crystallinity than a metal nitride film epitaxially grown on a YSZ substrate with a (111) plane orientation or an a-plane sapphire substrate with a (110) plane orientation. High-temperature conditions are generally necessary for epitaxial growth but are not required in this method. In addition, the metal oxynitride film can be easily formed by a sputtering method.

Since the epitaxially grown metal oxynitride film has a wurtzite structure, the metal oxynitride film functions as a buffer layer suitable for alleviating lattice mismatch between the substrate and the metal nitride film. In the case where the metal oxynitride film and the metal nitride film are used in a semiconductor device, the metal nitride film preferably has high crystallinity.

For example, in the case where an inorganic light-emitting element is formed using a metal nitride, a metal nitride film includes at least an n-type clad layer, an active layer, and a p-type clad layer. Thus, the metal nitride film stacked on a buffer layer preferably has higher crystallinity than the buffer layer. Higher crystallinity improves the uniformity of the carrier concentration or the like in the metal nitride film, resulting in improvement in electric characteristics. Higher crystallinity also increases the breakdown voltage and the reliability against current of the inorganic light-emitting element. Embodiment 2 details an example of manufacturing an inorganic light-emitting element or a display device including a metal oxynitride film and a metal nitride film.

Note that the semiconductor device including a metal oxynitride film and a metal nitride film is not limited to a display element and a display device. A projection device, a lighting device, an electro-optical device, a power storage device, a memory device, a semiconductor circuit, an imaging device, a communication device, an electronic device, or the like can be used as the semiconductor device.

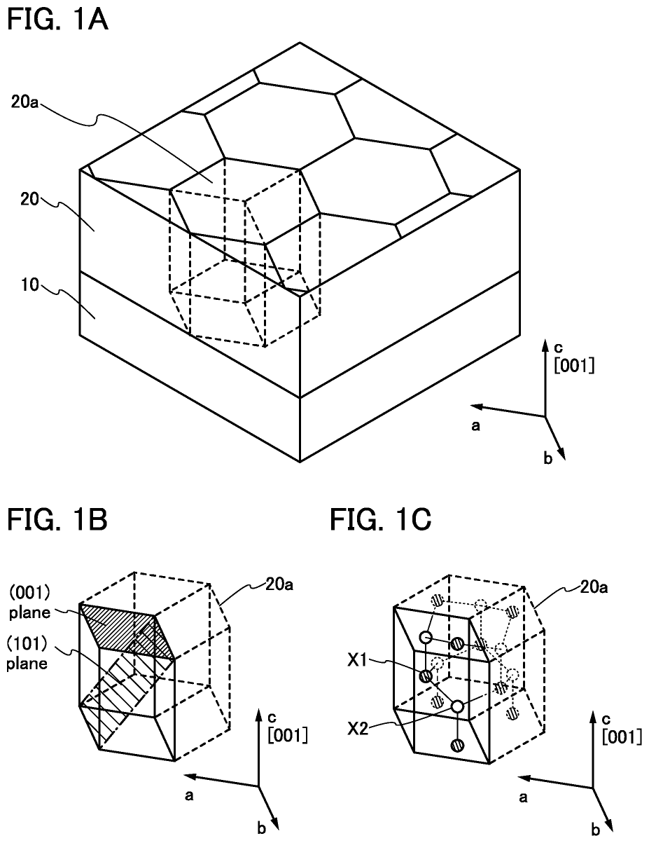

FIG. 1A is a schematic diagram of a structure body including a metal oxynitride film that is epitaxially grown on a single crystal substrate. FIG. 1A is the schematic diagram of the structure body in which a metal oxynitride film 20 is deposited on a single crystal substrate 10. FIG. 1A illustrates the case where the metal oxynitride film 20 includes a crystal 20a with a wurtzite structure. The metal oxynitride film 20 is epitaxially grown by the manufacturing method of one embodiment of the present invention so that a c-axis ([001] orientation) of the crystal 20a with a wurtzite structure corresponds to the normal direction of a surface of the single crystal substrate 10. Here, since the c-axis ([001] orientation) of the crystal included in the film epitaxially grown by the manufacturing method of one embodiment of the present invention corresponds to the normal direction of the surface of the single crystal substrate, the film that is epitaxially grown by the manufacturing method of one embodiment of the present invention is referred to as a c-axis epitaxial film in some cases. Note that the normal direction may be referred to as a perpendicular direction.

A crystal plane of the wurtzite structure is described with reference to FIG. 1B. FIG. 1B illustrates typical crystal planes (a (001) plane and a (101) plane) of the wurtzite structure. The (001) plane of the wurtzite structure illustrated in FIG. 1B is a plane parallel to the surface of the single crystal substrate 10.

FIG. 1C illustrates atomic arrangement in the wurtzite structure. In FIG. 1C, a position X1 is a position for a metal atom, and a position X2 is a position for an oxygen atom or a nitrogen atom. Note that the position X1 may be the position for an oxygen atom or a nitrogen atom, and the position X2 may be the position for a metal oxide atom.

A sputtering target used for the sputtering method is preferably an oxide target containing zinc, further preferably an oxide target containing at least one of indium and gallium, and zinc. As the oxide target, a zinc oxide target, an indium zinc oxide (In—Zn oxide) target, a gallium zinc oxide (Ga—Zn oxide) target, an indium gallium zinc oxide (In—Ga—Zn oxide) target, or the like can be used, for example. In particular, an indium gallium zinc oxide target is preferably used as the oxide target. The crystal structures of indium nitride, gallium nitride, and zinc oxide are each a wurtzite structure. Therefore, deposition with the oxide target facilitates formation of an in-plane oriented metal oxynitride thin film including a crystal with a wurtzite structure. Note that a thin film with a wurtzite structure is sometimes formed even by using the oxide target that does not have a wurtzite structure.

Another example of a sputtering target used for the sputtering method is preferably an oxide target containing indium, further preferably an oxide target containing indium and tin. As the oxide target, an indium oxide target or an indium tin oxide (ITO) target can be used, for example. In general, the crystal structures of indium oxide and indium tin oxide are each a bixbyite (C-type rare earth) structure. Therefore, deposition with the oxide target facilitates formation of an in-plane oriented metal oxide thin film with a bixbyite structure.

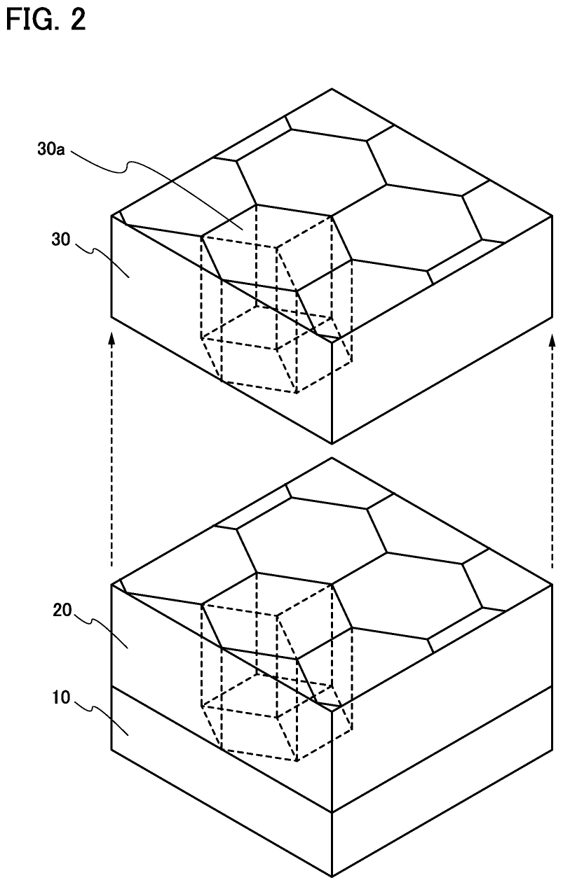

FIG. 2 is a schematic diagram of a structure body including a metal nitride film 30 that is epitaxially grown on the metal oxynitride film 20 with a wurtzite structure. The metal nitride film 30 includes a crystal 30a with a wurtzite structure. The (001) plane of the wurtzite structure of the metal oxynitride film 20 is a plane parallel to the crystal plane of the epitaxially grown metal nitride film 30, so that the metal nitride film 30 has high crystallinity. Note that the metal nitride film 30 preferably contains at least a Group 13 element and a Group 15 element.

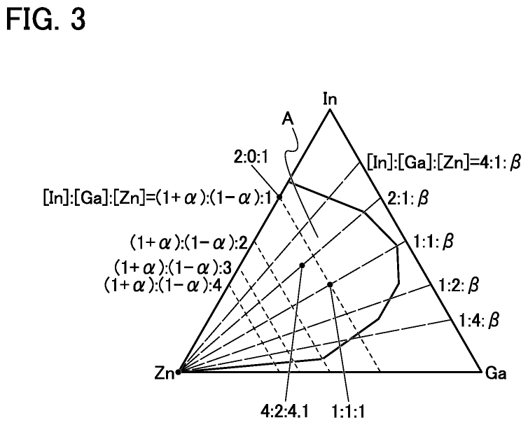

A preferred range of the atomic ratio of metals contained in the oxide target containing zinc is described with reference to FIG. 3. FIG. 3 shows the atomic ratio of indium, gallium, and zinc contained in the oxide target. Note that the proportion of oxygen atoms is not shown in FIG. 3. In addition, the terms of the atomic ratio of indium, gallium, and zinc contained in the oxide target are denoted by [In], [Ga], and [Zn], respectively.

In FIG. 3, broken lines indicate a line representing the atomic ratio of [In]:[Ga]:[Zn]=(1+α): (1−α):1 (α is a real number of −1 to 1), a line representing the atomic ratio of [In]:[Ga]:[Zn] =(1+α):(1−α):2, a line representing the atomic ratio of [In]:[Ga]:[Zn]=(1+α): (1−α):3, and a line representing the atomic ratio of [In]:[Ga]:[Zn]=(1+α):(1−α):4.

Furthermore, dashed-dotted lines indicate a line representing the atomic ratio of [In]:[Ga]:[Zn]=4:1:β (β is a real number of 0 or more), a line representing the atomic ratio of [In]:[Ga]:[Zn]=2:1:β, a line representing the atomic ratio of [In]:[Ga]:[Zn]=1:1:β, a line representing the atomic ratio of [In]:[Ga]:[Zn]=1:2: β, and a line representing the atomic ratio of [In]:[Ga]:[Zn]=1:4:β.

A region A shown in FIG. 3 represents an example of the preferred range of the atomic ratio of indium, gallium, and zinc contained in the oxide target. The region A includes In—Ga—Zn oxide targets with [In]:[Ga]:[Zn]=4:2:4.1 and [In]:[Ga]:[Zn]=1:1:1, an In—Zn oxide target with [In]:[Ga]:[Zn]=2:0:1 ([In]:[Zn]=2:1), and a zinc oxide target with [In]:[Ga]:[Zn]=0:0:1.

Note that the sputtering target used for the sputtering method is not limited to an oxide target and may be an oxynitride target. As the oxynitride target, for example, an indium gallium zinc oxynitride (In—Ga—Zn oxynitride) target, an indium gallium oxynitride (In—Ga oxynitride) target, or the like can be used.

A substrate temperature during the deposition of the metal oxynitride film is preferably higher than or equal to a room temperature (25° C.) and lower than or equal to 500° C., further preferably higher than or equal to 80° C. and lower than or equal to 400° C., still further preferably higher than or equal to 150° C. and lower than or equal to 350° C. Since deposition can be performed at a substrate temperature lower than or equal to 500° C., the productivity of a semiconductor device or the like using the metal oxynitride film can be improved.

A gas containing a nitrogen gas is preferably used as the gas introduced into the reaction chamber for the deposition of the metal oxynitride film. For example, it is preferable that a nitrogen gas, a mixed gas of a nitrogen gas and an oxygen gas, a mixed gas of a nitrogen gas and a rare gas (e.g., argon or helium), or the like be used as the gas. Here, the flow rate of the nitrogen gas is preferably higher than or equal to 50% and lower than or equal to 100%, further preferably higher than or equal to 70% and lower than or equal to 100%, still further preferably higher than or equal to 85% and lower than or equal to 100% of the total flow rate of the gas. The composition of the metal oxynitride film to be obtained can be adjusted by adjustment of the flow rate ratio of the nitrogen gas to the flow rate of the gas.

### <Sputtering Apparatus>

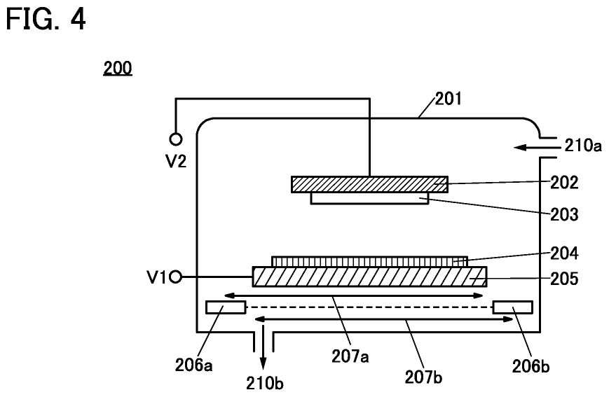

Next, a sputtering apparatus that is involved in the method for manufacturing a metal oxynitride film of one embodiment of the present invention is described with reference to FIG. 4. FIG. 4 is a cross-sectional view showing a deposition chamber 201 included in a sputtering apparatus 200.

The deposition chamber 201 illustrated in FIG. 4 includes a substrate holder 202, a sputtering target 204, a backing plate 205, and a magnet unit 206. The number of magnet units 206 may be one or two or more (e.g., a magnet unit 206a and a magnet unit 206b). The magnet unit 206 may be fixed or have an oscillation mechanism. Note that the sputtering target 204 is positioned and fixed over the backing plate 205. The magnet unit 206 is positioned under the sputtering target 204 with the backing plate 205 therebetween. When a substrate 203 is transferred into the deposition chamber 201, the substrate 203 is positioned in contact with the substrate holder 202. The deposition chamber 201 includes an inlet 210a for supplying gas (also referred to as a deposition gas) and an outlet 210b. A deposition gas is supplied to the deposition chamber 201 through the inlet 210a and exhausted through the outlet 210b.

FIG. 4 illustrates an example in which the magnet unit 206a and the magnet unit 206b are provided. The magnet unit 206a and the magnet unit 206b each have an oscillation mechanism: the magnet unit 206a has an oscillation range 207a and the magnet unit 206b has an oscillation range 207b. When the magnet unit 206a and the magnet unit 206b are oscillated in the range where the sputtering target 204 is positioned, a uniform film can be formed. For example, the magnet unit 206a or the magnet unit 206b can be oscillated with a beat (also referred to as rhythm, count, pulse, frequency, period, cycle, or the like) of greater than or equal to 0.1 Hz and less than or equal to 1 kHz.

The magnetic field that the sputtering target 204 receives is determined by a voltage V2 applied to the substrate holder 202 and a voltage V1 applied to the backing plate 205. In addition, the magnetic field that the sputtering target 204 receives changes in accordance with oscillation of the magnet unit 206. A region with an intense magnetic field is a high-density plasma region; thus, a sputtering phenomenon of the sputtering target 204 easily occurs in the vicinity of the region. In the case where the sputtering target 204 contains a plurality elements, the intensity of the magnetic field applied from the magnet unit 206a to the sputtering target 204 can differentiate from the intensity of the magnetic field applied from the magnet unit 206b to the sputtering target 204. Elements based on the magnetic field intensity are deposited on the substrate 203.

FIG. 4 illustrates an example in which a parallel-plate sputtering apparatus is used; however, the method for depositing a metal oxynitride film according to this embodiment is not limited thereto. For example, a metal oxynitride film may be deposited using a facing-target sputtering apparatus.

A sputtering method, which enables low-temperature deposition, can increase the productivity of a semiconductor device or the like using the metal oxynitride film.

According to one embodiment of the present invention, a method for depositing a metal oxynitride film by epitaxial growth at a low temperature can be provided. According to another embodiment of the present invention, a method for depositing a metal oxynitride film by epitaxial growth without high-temperature treatment before and after the deposition of the metal oxynitride film can be provided. According to another embodiment of the present invention, a method for depositing a metal nitride film by epitaxial growth on a metal oxynitride film without high-temperature treatment can be provided. According to another embodiment of the present invention, a semiconductor device or the like including a metal nitride film deposited by epitaxial growth on a metal oxynitride film can be provided. According to another embodiment of the present invention, the productivity of a semiconductor device or the like including a metal nitride film can be increased.

### <Method for Evaluating Crystallinity and Orientation of Thin Film>

Evaluation of epitaxial growth can be conducted during or after deposition of the thin film depending on an evaluation method.

Examples of a method for evaluating epitaxial growth during deposition of the thin film include reflection high energy electron diffraction (RHEED) and surface photoabsorption (SPA).

Epitaxial growth (crystallinity and orientation) of a deposited thin film can be evaluated by a combination of a transmission electron microscope (TEM); reciprocal space mapping, pole measurement (ϕ scanning), Out-of-Plane measurement, and In-Plane measurement of an X-ray diffraction (XRD) method; and the like.

A measurement method that can be used for evaluating the crystallinity and orientation of a thin film will be described below.

### <Reciprocal Space Mapping>

Reciprocal space mapping is described.

A reciprocal space is a space that is composed of a basic vector of a reciprocal space (also referred to as a reciprocal vector) and reflects the periodicity of the real space. Here, a reciprocal vector bⱼ and a basic vector aᵢ of the real space have a relationship shown in the following formula (1). That is, a plane defined in a crystal of the real space is regarded as a lattice point in a reciprocal lattice.

[Formula 2]

aᵢ·bⱼ=2πδ_{i,j} (2)

An epitaxially grown thin film has a small variation in the crystal orientation of crystals included in the thin film, i.e., high orientation. Thus, when a reciprocal space map of the epitaxially grown thin film is obtained, the intensity of an observed spot is high, and a full width at half maximum (FWHM) of the spot is small. In contrast, when a reciprocal space map of a thin film with a large variation in the crystal orientation, i.e., low orientation, of the crystals, is obtained, the intensity of an observed spot is low and the full width at half maximum of the spot is large. In this manner, the reciprocal space map is obtained, whereby the crystallinity and orientation of the thin film can be evaluated.

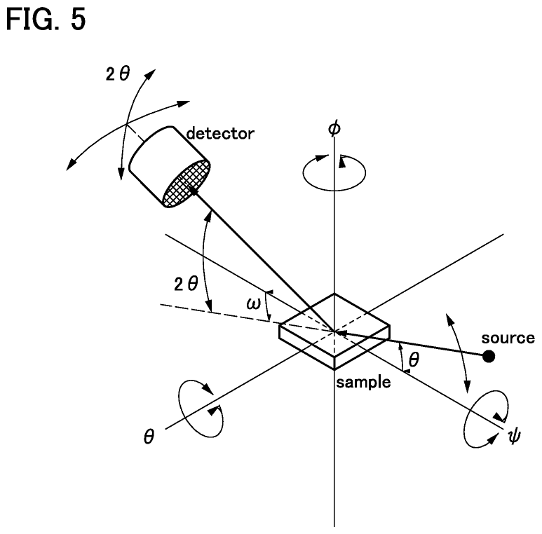

An apparatus that can be used in an X-ray analysis is described with reference to FIG. 5. Here, as illustrated in FIG. 5, a direction in which an X-ray source (source), a sample, and a detector are arranged in line when the X-ray analysis apparatus is seen from the above is referred to as a ψ axis. A direction perpendicular to the ψ axis when the X-ray analysis apparatus is seen from the above is referred to as a θ axis. A direction perpendicular to the ψ axis and the θ axis is referred to as a ϕ axis. That is, the ϕ axis is parallel to the direction in which the X-ray analysis apparatus is seen from the above. Note that an axis that is referred to as the ψ axis in this specification is referred to as a χ axis depending on an apparatus in some cases. Therefore, the ψ axis can also be referred to as a χ axis. Similarly, an axis that is referred to as the θ axis in this specification is referred to as a ψ axis depending on an apparatus in some cases. Thus, the θ axis can also be referred to as a ψ axis.

A two-dimensional detector may be used as the detector. The two-dimensional detector has positional information for 20 and the χ direction in the detection surface. Note that the detector illustrated in FIG. 5 is modeled on a two-dimensional detector. Note that unless otherwise specified, a value obtained with a CuKα ray (wavelength: 0.15418 nm) used as the X-ray source is used in this specification.

### <Pole Measurement>

Pole measurement is a method for measuring the distribution of diffraction intensity by rotating a sample in various directions with the positions (angles) of the X-ray source and the detector kept constant.

Analysis of scanning in a ϕ direction with respect to a predetermined crystal plane of a sample is referred to as ϕ scanning, and a smaller full width at half maximum (also referred to as Δϕ) in ϕ scanning means better in-plane orientation. The in-plane orientation is sometimes referred to as crystallinity in the specification.

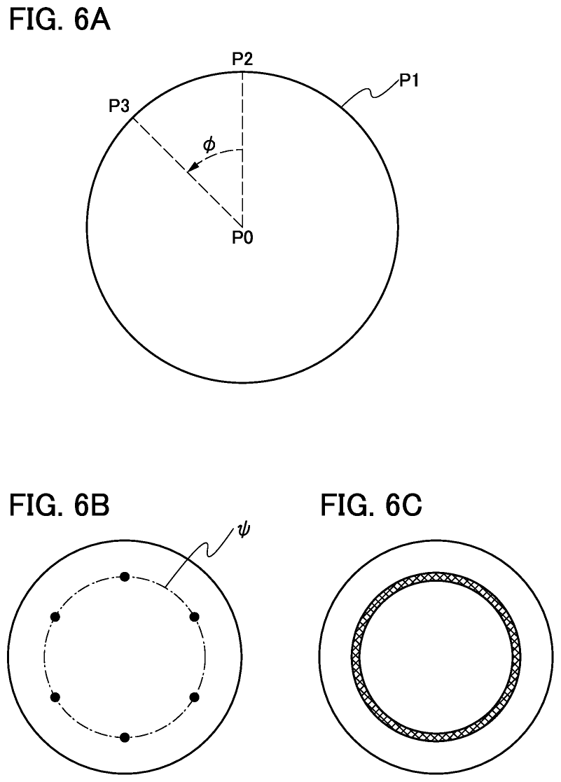

The diffraction intensity obtained by the pole measurement is described with reference to FIG. 6. The diffraction intensity obtained by the pole measurement is shown by a pole figure. FIG. 6A illustrates a pole figure. As illustrated in FIG. 6A, the center P0 of the pole figure has an angle ψ of 0°, and the outer periphery P1 of the pole figure has an angle ψ of 90°. A straight line that extends right above from the center P0 of the pole figure to the outer periphery P1 of the pole figure (a straight line denoted by a dashed dotted line P0-P2 in FIG. 6A) has an angle ϕ of 0°, and an angle formed by the straight line and a straight line that extends from the center P0 of the pole figure to the outer periphery P1 of the pole figure (a straight line denoted by a dashed dotted line P0-P3 in FIG. 6A) becomes the angle ϕ. Although FIG. 6A shows that the angle ϕ increases in the case of counterclockwise rotation; however, it is not limited thereto, and the angle ϕ increases in the case of clockwise rotation in some cases depending on the apparatus or the like. In addition, the angle of the pole figure obtained by the pole measurement is not obtained in some cases within a range of 0° to 90° depending on the range of ψ scanning. Note that in the pole measurement, an axis that is referred to as the ψ axis in this specification is referred to as an a axis depending on an apparatus in some cases. Therefore, ψ can also be referred to as α. Similarly, an axis that is referred to as the ϕ axis in this specification is referred to as a β axis depending on an apparatus in some cases. Thus, θ can also be referred to as β.

FIG. 6B and FIG. 6C are schematic diagrams of the diffraction intensity obtained by pole measurement. FIG. 6B is a schematic diagram of the diffraction intensity in the case where spot-like intensity distribution is observed on a concentric circle of the angle ψ (a circle denoted by a dashed dotted line in the figure), and FIG. 6C is a schematic diagram of the diffraction intensity in the case where a ring-like intensity distribution is observed.

For example, the (101) plane of the wurtzite structure has six-fold symmetry. In other words, when pole measurement is performed on a c-axis epitaxial thin film having a crystal with a wurtzite structure, spot-like intensity distribution (diffraction peak) is observed at six points on a concentric circle of a certain angle ψ, as shown in FIG. 6B. Thus, in the case where a thin film having a crystal with a wurtzite structure is epitaxially grown along the c-axis, diffraction peaks indicating six-fold symmetry are observed in pole measurement or ϕ scanning on the (101) plane of the crystal of the thin film. Specifically, diffraction peaks are observed at approximately every 60° on a concentric circle with an angle ψ of approximately 62°.

On the other hand, when pole measurement is performed on a thin film that is not epitaxially grown, ring-like intensity distribution as shown in FIG. 6C is observed, or no diffraction peak is observed. In this manner, the analysis on the intensity distribution observed in the pole measurement enables evaluation on whether the thin film is epitaxially grown.

Note that diffraction peaks indicating three-fold symmetry are observed in pole measurement or ϕ scanning on a (220) plane of a single crystal YSZ substrate. Specifically, diffraction peaks are observed at approximately every 120° on a concentric circle with an angle ψ of approximately 35°. In addition, diffraction peaks indicating two-fold symmetry are observed in pole measurement or ϕ scanning on a (300) plane of a single crystal a-plane sapphire substrate. Specifically, diffraction peaks are observed at approximately every 180° on a concentric circle with an angle ψ of approximately 30°.

### <Out-of-Plane Measurement and In-Plane Measurement>

Out-of-plane measurement and In-plane measurement are given as measurement employing an XRD method. Out-of-plane measurement is a method for evaluating a crystal plane parallel to a surface of a thin film, and In-plane measurement is a method for evaluating a crystal plane perpendicular to a surface of a thin film. A zero-dimensional detector may be used as the detector in Out-of-plane measurement and In-plane measurement.

The structure, method, and the like described above in this embodiment can be used in appropriate combination with structures, methods, and the like described in the other embodiments and the example.

### Embodiment 2

In this embodiment, application of the epitaxially grown metal oxynitride film described in the above embodiment will be described.

Examples of the application of the metal oxynitride film include an inorganic light-emitting element, a light-receiving element, a power semiconductor element, and a semiconductor device. In particular, the metal oxynitride film is preferably used in an inorganic light-emitting element. Note that the inorganic light-emitting element includes an LED (Light Emitting Diode) and a micro LED.

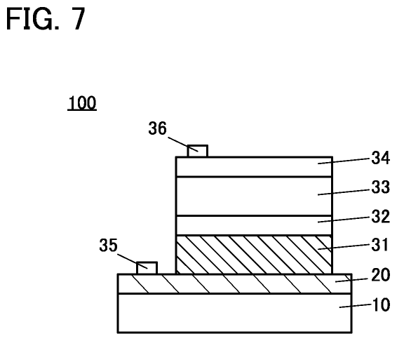

Structure examples of an inorganic light-emitting element including the metal oxynitride film are described with reference to FIG. 7. Note that in this embodiment, an inorganic light-emitting element having a double heterojunction is described. Note that one embodiment of the present invention is not limited thereto, and an inorganic light-emitting element having a quantum well junction may be used.

FIG. 7 illustrates an inorganic light-emitting element 100 including a metal nitride film formed over the metal oxynitride film of one embodiment of the present invention. As illustrated in FIG. 7, the inorganic light-emitting element 100 includes the substrate 10, a buffer layer formed using the metal oxynitride film 20, an n-type clad layer 31, an active layer 32, a p-type clad layer 33, an electrode 35, and an electrode 36. The n-type clad layer 31, the active layer 32, and the p-type clad layer 33 can be formed using a metal nitride film. Note that a conductor 34 may be provided between the p-type clad layer 33 and the electrode 36. The metal oxynitride film 20 has conductivity and functions as an electrode of the inorganic light-emitting element 100. In the inorganic light-emitting element 100, for example, the metal oxynitride film 20 and the conductor 34 are used as a cathode electrode and an anode electrode, respectively.

Note that the n-type clad layer 31, which is the metal nitride film, can have an ohmic contact with the electrode 35 through the metal oxynitride film 20. The p-type clad layer 33, which is the metal nitride film, can have an ohmic contact with the electrode 36 through the conductor 34.

The active layer 32 is sandwiched between the n-type clad layer 31 and the p-type clad layer 33. In the active layer 32, electrons and holes are combined to emit light. That is, the active layer 32 can be referred to as a light-emitting layer. For example, the n-type clad layer 31 preferably contains silicon, germanium, tin, or the like as an n-type dopant. The p-type clad layer 33 preferably contains magnesium or the like as a p-type dopant. The active layer 32 preferably contains indium, zinc, silicon, or the like.

The atomic ratio of the metals included in the metal oxynitride film 20 of one embodiment of the present invention, the dopant added to the metal nitride film, the flow rate of a nitrogen gas introduced to the reaction chamber at deposition, and the like are appropriately selected, whereby the conductivity (or insulating property), band gap, light-transmitting property, and the like of the metal oxynitride film 20 and the metal nitride film can be adjusted. For example, as the flow rate of the nitrogen gas increases, the crystallinity and the conductivity of the film tend to increase.

In addition, the metal oxynitride film 20 can function as a buffer layer for making a metal nitride thin film epitaxially grow on the film. Thus, the crystallinity of the n-type clad layer 31, the active layer 32, and the p-type clad layer 33 formed over the metal oxynitride film 20 can be increased. Note that the metal nitride film as well as the metal oxynitride film 20 has a hexagonal crystal structure, particularly a wurtzite crystal structure. Therefore, a material forming a wurtzite crystal structure, such as gallium nitride or a compound of indium and gallium nitride, is preferably used for the n-type clad layer 31 or the active layer 32 formed over the metal oxynitride film 20.

Thus, the metal oxynitride film 20 has a function of a buffer layer for hexagonal crystal growth and has a function of an electrode. When the metal oxynitride film 20 is used as the buffer layer, the n-type clad layer 31 or the active layer 32 is easily epitaxially grown, and the crystallinity of the n-type clad layer 31 or the active layer 32 is increased. Accordingly, the characteristics of the inorganic light-emitting element, such as the light emission efficiency and durability life, can be improved.

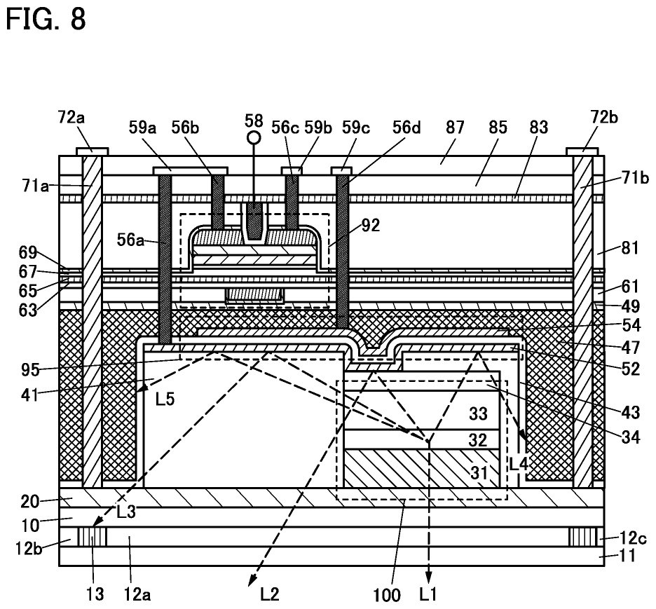

FIG. 8 is a diagram illustrating a structure example of a semiconductor device. The semiconductor device includes an inorganic light-emitting element, a transistor, and a capacitor. Thus, one embodiment of the present invention describes a structure example of the semiconductor device that is used in a pixel of a display device. Note that the display device described in FIG. 8 can be used in a lighting device. The use of the inorganic light-emitting element of one embodiment of the present invention allows fabricating a highly reliable display device with high emission efficiency.

The pixel includes the inorganic light-emitting element 100, a transistor 92, and a capacitor 95. The inorganic light-emitting element 100 is formed over the substrate 10 with the metal oxynitride film 20 therebetween. The inorganic light-emitting element 100 is constituted by forming the n-type clad layer 31, the active layer 32, the p-type clad layer 33, and the conductor 34 in this order over the metal oxynitride film 20.

The capacitor 95 is formed over the conductor 34 and the transistor 92 is formed over the capacitor 95. A substrate 11 is provided on a surface of the substrate 10, which is opposite to the surface where the inorganic light-emitting element 100 is formed, with a functional layer 12 therebetween. Note that the functional layer 12 preferably includes one or both of a coloring layer and a color conversion layer for each pixel. Note that the functional layer 12 is preferably positioned so as to overlap with the pixel. The functional layer 12 includes a functional layer 12a to a functional layer 12c, and a region of each of the functional layer 12a to the functional layer 12c that overlaps with the pixel is determined by a light-shielding layer 13.

Although FIG. 8 illustrates an example in which the pixel includes one transistor for simplicity of the drawing, the number of transistors is not limited to one. A plurality of transistors can be positioned so as to overlap with the capacitor. Note that the transistor can be positioned so as to overlap with the inorganic light-emitting element and the capacitor. For example, the pixel may have a structure including a plurality of transistors.

An insulator 41 is formed so as to cover the inorganic light-emitting element 100. Thus, the insulator 41 is preferably in contact with the conductor 34 and the metal oxynitride film 20. A conductor 52 is formed over the insulator 41. The conductor 52 functions as one electrode of the capacitor 95. Note that the conductor 52 is electrically connected to the conductor 34 through an opening portion of the insulator 41 formed over the inorganic light-emitting element 100. The conductor 52 functions as a reflective film that reflects light emitted from the inorganic light-emitting element 100.

An insulator 43 is formed over the conductor 52. The insulator 43 is preferably in contact with the insulator 41 and the metal oxynitride film 20. A conductor 54 is formed over the insulator 43. Note that the conductor 54 functions as the other electrode of the capacitor 95. Thus, the capacitor 95 is formed in a region where the conductor 54 overlaps with the conductor 52 with the insulator 43 therebetween.

An insulator 47 is formed over the conductor 54. Note that the insulator 47 is preferably in contact with the insulator 43. In addition, the insulator 47 is preferably a coloring layer. The coloring layer preferably reduces transmission of light emitted from the inorganic light-emitting element 100.

The conductor 52 and the conductor 54 can be formed using a metal film containing an element selected from molybdenum, titanium, tantalum, tungsten, aluminum, silver, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. Note that the conductor 52 is preferably formed using a high reflectance metal film (aluminum, an alloy containing aluminum, silver, or the like).

The inorganic light-emitting element 100 emits light L1 to light L5, for example. In the case where the substrate 11 is a display surface of the display device, the light L1 emitted from the inorganic light-emitting element 100 can contribute to display. The light L2 to the light L5 are emitted in the direction of the capacitor 95. The light L2 is emitted through the display surface with one electrode of the capacitor 95 serving as a reflective film. Note that the light L3 reflected by the reflective film is attenuated by the light-shielding layer 13 before emitted through the display surface. The light-shielding layer 13 can prevent the light L3 reflected by the reflective film from being emitted through the functional layer 12b of an adjacent pixel. The light L4 and the light L5 reflected by the reflective film can be prevented from entering adjacent pixels. Thus, the insulator 47 can maintain the purity and luminance of light emitted from the pixel and reduce the effect of light emitted from other pixels.

Note that the top surface of the insulator 47 is preferably planarized by planarization treatment using a chemical mechanical polishing (CMP) method or the like to improve planarity. The transistor 92 is formed over the insulator 47.

An insulator 49 and an insulator 61 are provided to be stacked in this order over the insulator 47. Furthermore, the transistor 92 is provided above the insulator 49. An insulator 81 is provided above the transistor 92. A BEOL (Back end of line) region forming wirings of the semiconductor device is provided above the transistor 92. For example, the BEOL region includes a conductor 59 (a conductor 59a to a conductor 59d) that connects the transistor 92 and the capacitor. A terminal 58 can be connected to the conductor 59. An insulator 83 is provided above the insulator 81. The conductor 58 functioning as a wiring is provided above the insulator 83. An insulator 85 is provided above the conductor 58 and the conductor 59 functioning as a wiring is provided above the insulator 85. An insulator 87 is provided above the conductor 59 and a conductor 72 (a conductor 72a and a conductor 72b) functioning as a terminal is provided above the insulator 87. Note that the transistor 92 is sometimes positioned so as to be partly embedded in parts of the insulator 49 and the insulator 61.

The conductor 58 and the conductor 59 shown in this embodiment each have, but are not limited to, a single-layer structure; they may each have a stacked-layer structure of two or more layers. For example, between a conductor having a barrier property and a conductor having high conductivity, a conductor that is highly adhesive to the conductor having a barrier property and the conductor having high conductivity may be formed.

Note that the conductor 58 and the conductor 59 can be formed using a conductive material such as a metal material, an alloy material, or a metal oxide material. It is preferable to use a high-melting-point material that has both heat resistance and conductivity, such as tungsten or molybdenum, and it is particularly preferable to use tungsten. In the case where the conductor 58 and the conductor 59 are formed in the same process as another component such as a conductor, copper (Cu), aluminum (Al), or the like, which is a low-resistance metal material, may be used.

A conductor 56 (a conductor 56a to a conductor 56d), a conductor 71 (a conductor 71a and a conductor 71b), or a conductor (e.g., a conductor 503) included in the transistor 92, and the like are positioned so as to be embedded in the insulator 47, the insulator 49, the insulator 61, the insulator 81, the insulator 83, the insulator 85, or the insulator 87. Note that the conductor 56 has a function of a plug or a wiring that is connected to the capacitor 95 and the transistor 92. The conductor 71 has a function of a plug or a wiring that is connected to the metal oxynitride film 20 functioning as the cathode electrode of the inorganic light-emitting element 100. Note that the metal oxynitride film 20 functions as a common electrode. Thus, one or more conductors 71 are preferably provided in the display device including a plurality of pixels. FIG. 8 illustrates, but is not limited to, an example in which one pixel includes the conductor 71a and the conductor 71b.

As a material for the conductor 56 and the conductor 71, a conductive material such as a metal material, an alloy material, a metal nitride material, or a metal oxide material can be used as a single layer or stacked layers. It is preferable to use a high-melting-point material that has both heat resistance and conductivity, such as tungsten or molybdenum, and it is particularly preferable to use tungsten. Alternatively, it is preferable to use a low-resistance conductive material such as aluminum or copper. The use of a low-resistance conductive material can reduce wiring resistance.

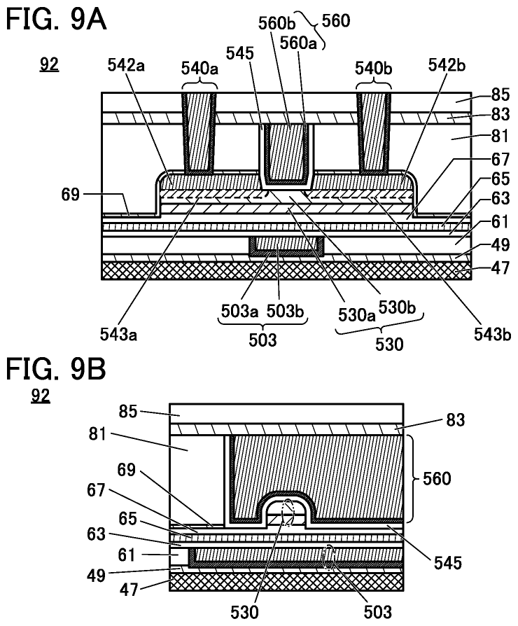

Note that an insulator 63, an insulator 65, an insulator 67, and an insulator 69 will be described in detail with reference to FIG. 9.

Next, the transistor 92 is described. A semiconductor layer of the transistor 92 preferably contains oxygen and further contains any one or more of In, Ga, Sn, and Zn. Thus, this can be expressed as that the semiconductor layer of the transistor 92 includes an oxide semiconductor. A transistor including an oxide semiconductor (OS), which is one kind of metal oxide, in a semiconductor layer where a channel of the transistor is formed is referred to as an “OS transistor” or “OS-FET”. It is known that the OS transistor has a small variation in electric characteristics due to temperature change. Furthermore, a semiconductor layer of the OS transistor has a large energy gap, and thus the OS transistor can have an extremely low off-state current of several yA/μm (a current value per micrometer of a channel width). Therefore, the OS transistor is preferably used for a memory device. Note that a detailed structure of the OS transistor will be described with reference to FIG. 9.

Here, a pixel using an OS transistor is described. The pixel using an OS transistor can inhibit deterioration of data retained in the pixel even when supply of electric power is stopped. Thus, the pixel enables a capacitor retaining data to be downsized, and therefore a display device suitable for an increase in density can be provided. Moreover, in the pixel utilizing an extremely low off-state current, the number of rewrites of still images can be reduced, and an intermittent driving leading to low power consumption (IDS driving) becomes possible.

Note that the IDS driving is idling stop driving for operation with a lower frame frequency than normal operation. In the IDS driving, rewriting of image data is stopped after writing processing of image data is performed. Increasing the interval between writing of image data and subsequent writing of image data can reduce the power that would be consumed by writing of image data in that interval. The frame frequency in the IDS driving can be higher than or equal to 1/100 and lower than or equal to 1/10 of that in the normal operation (typically, higher than or equal to 60 Hz and lower than or equal to 240 Hz). Video signals for a still image are the same between consecutive frames. Thus, the IDS driving mode is particularly effective in displaying a still image.

The off-state current of the OS transistor hardly increases even in high-temperature environments. Specifically, the off-state current hardly increases even at an environment temperature higher than or equal to room temperature and lower than or equal to 200° C. In addition, the on-state current of the OS transistor is unlikely to decrease even in high-temperature environments. An OS transistor has high breakdown voltage between its source and drain. Even in the case where the temperature of the inorganic light-emitting element increases, when OS transistors are used as transistors included in a display device, a lighting device, or the like, stable operation can be achieved even in high-temperature environments, offering a highly reliable display device, lighting device, or the like.

The OS transistor can be formed by a sputtering method in a BEOL process for forming a wiring of a semiconductor device. Thus, one semiconductor device can be formed using transistors with different characteristics. In other words, the use of the OS transistor facilitates formation of an SOC (System on chip).

Note that the OS transistor can have a back gate. The back gate is positioned so that a channel formation region of a semiconductor layer is sandwiched between the gate and the back gate. The back gate can function like the gate. In addition, by changing the voltage of the back gate, the threshold voltage of the transistor can be changed. The voltage of the back gate may be the same as that of the gate or may be a GND voltage or a given voltage.

In general, the gate and the back gate are formed using conductive layers and thus each have a function of preventing an electric field generated outside the transistor from influencing the semiconductor layer in which a channel is formed (particularly, a function of preventing static electricity). That is, the variation in the electrical characteristics of the transistor due to the influence of external electric field such as static electricity can be prevented.

Next, the insulator 41, the insulator 43, the insulator 47, the insulator 49, the insulator 61, the insulator 85, and the insulator 87 are described. A substance having a barrier property against oxygen or hydrogen is preferably used for any of these insulators.

In particular, the insulator 49 and the insulator 61 are preferably formed using a film having a barrier property that prevents hydrogen or impurities from diffusing from a region or the like where the inorganic light-emitting element 100 is provided into a region where the transistor 92 is provided. In addition, the insulator 83 is preferably formed using a film having a barrier property that prevents hydrogen or impurities from diffusing from the outside into a region where the transistor 92 is provided.

For the film having a barrier property against hydrogen, for example, silicon nitride formed by a CVD method can be used. Here, diffusion of hydrogen into a semiconductor element including an oxide semiconductor, such as the transistor 92, degrades the characteristics of the semiconductor element in some cases. Therefore, a film that inhibits hydrogen diffusion is preferably provided between the transistor 92 and the inorganic light-emitting element. Specifically, the film that inhibits hydrogen diffusion is a film from which a small amount of hydrogen is released.

The amount of released hydrogen can be analyzed by thermal desorption spectroscopy (TDS) analysis, for example. The amount of hydrogen released from the insulator 49 that is converted into hydrogen atoms per area of the insulator 49 is less than or equal to 10×10¹⁵ atoms/cm², preferably less than or equal to 5×10¹⁵ atoms/cm² in TDS analysis in a film-surface temperature range of 50° C. to 500° C., for example.

For the film having a barrier property against hydrogen, for example, silicon nitride formed by a CVD method can be used. Here, diffusion of hydrogen into a semiconductor element including an oxide semiconductor, such as the transistor 92, degrades the characteristics of the semiconductor element in some cases. Therefore, a film that inhibits hydrogen diffusion is preferably provided between the transistor 92 and the inorganic light-emitting element 100. Specifically, the film that inhibits hydrogen diffusion is a film from which a small amount of hydrogen is released.

In particular, silicon nitride has an excellent blocking effect that prevents the passage of both oxygen and impurities such as hydrogen and moisture that cause a change in electrical characteristics of the transistor. Accordingly, silicon nitride can prevent mixing of impurities such as hydrogen and moisture into the transistor 92 during and after a manufacturing process of the transistor. In addition, release of oxygen from the oxide contained in the transistor 92 can be inhibited. Therefore, silicon nitride is suitably used for a protective film of the transistor 92.

Moreover, for example, the insulator 61 preferably has a lower permittivity than the insulator 49. For example, the relative permittivity of the insulator 61 is preferably lower than 4, further preferably lower than 3. The relative permittivity of the insulator 61 is, for example, preferably 0.7 times or less, further preferably 0.6 times or less the relative permittivity of the insulator 49. When a material with a low permittivity is used for the interlayer film, the parasitic capacitance generated between wirings can be reduced. A silicon oxide film, a silicon oxynitride film, or the like can be used for the insulator 61, for example.

In addition, the conductor 56 and the conductor 71 in a region in contact with the insulator 49 are each preferably a conductor having a barrier property against oxygen, hydrogen, and water. With this structure, the inorganic light-emitting element 100 and the transistor 92 can be separated by the layer having a barrier property against oxygen, hydrogen, and water; thus, the diffusion of hydrogen from the inorganic light-emitting element 100 into the transistor 92 can be inhibited.

Next, the substrate is described. Since the substrate 10 is positioned on the side where light from the light-emitting diode is extracted, a material having a high visible light-transmitting property is preferably used for the substrate 10. Examples of a material that can be used for the substrate 10 and the substrate 11 include sapphire, yttria-stabilized zirconia, glass, quartz, and a resin. A film such as a resin film, or the like may be used as the substrate 10 and the substrate 11. In that case, the display device can be reduced in weight and thickness.

For the color conversion layer, a phosphor or a quantum dot (QD) is preferably used. In particular, a quantum dot has an emission spectrum with a narrow peak width, so that emission with high color purity can be obtained. Accordingly, the display quality of the display device can be improved.

The color conversion layer can be formed by a droplet discharge method (e.g., an inkjet method), a coating method, an imprinting method, a variety of printing methods (screen printing or offset printing), or the like. A color conversion film such as a quantum dot film may also be used.

For processing a film to be the color conversion layer, a photolithography method is preferably employed. As a photolithography method, there are a method in which a resist mask is formed over a thin film to be processed, the thin film is processed by etching or the like, and the resist mask is removed, and a method in which a photosensitive thin film is formed, and then exposed to light and developed to be processed into a desired shape. For example, a thin film is formed using a material in which a quantum dot is mixed with a photoresist, and the thin film is processed by a photolithography method, whereby an island-shaped color conversion layer can be formed.

There is no particular limitation on a material of a quantum dot, and examples include a Group 14 element, a Group 15 element, a Group 16 element, a compound of a plurality of Group 14 elements, a compound of an element belonging to any of Group 4 to Group 14 elements and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and a variety of semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and combinations thereof. What is called an alloyed quantum dot whose composition is represented by a given ratio may also be used.

Examples of the quantum dot include core-type quantum dots, core-shell quantum dots, and core-multishell quantum dots. Quantum dots have a high proportion of surface atoms and thus have high reactivity and easily aggregate together. For this reason, it is preferable that a protective agent be attached to, or a protective group be provided on the surfaces of quantum dots. The attachment of the protective agent or the provision of the protective group can prevent aggregation and increase solubility in a solvent. It can also reduce reactivity and improve electrical stability.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size becomes smaller; thus, the emission wavelengths of the quantum dots can be adjusted over a wavelength range of a spectrum of an ultraviolet region, a visible light region, and an infrared region by changing the sizes of quantum dots. The size (diameter) of the quantum dot is, for example, greater than or equal to 0.5 nm and less than or equal to 20 nm, preferably greater than or equal to 1 nm and less than or equal to 10 nm. The emission spectra are narrowed as the size distribution of the quantum dots gets smaller, so that light with high color purity can be obtained. The shape of the quantum dot is not particularly limited and may be a spherical shape, a rod shape, a circular shape, or other shapes. Quantum rods, which are rod-shaped quantum dots, have a function of emitting directional light.

The coloring layer is a colored layer that transmits light in a specific wavelength range. For example, a color filter that transmits light in a red, green, blue, or yellow wavelength range can be used. Examples of a material that can be used for the coloring layer include a metal material, a resin material, and a resin material containing a pigment or a dye.

As shown in FIG. 9A and FIG. 9B, the transistor 92 includes the conductor 503 positioned so as to be embedded in the insulator 49 and the insulator 61; the insulator 63 positioned over the insulator 61 and the conductor 503; the insulator 65 positioned over the insulator 63; the insulator 67 positioned over the insulator 65; an oxide 530a positioned over the insulator 67; an oxide 530b positioned over the oxide 530a; a conductor 542a and a conductor 542b positioned apart from each other over the oxide 530b; the insulator 81 that is positioned over the conductor 542a and the conductor 542b and is provided with an opening formed to overlap with a region between the conductor 542a and the conductor 542b; an insulator 545 positioned on a bottom and a side surface of the opening; and a conductor 560 positioned on a formation surface of the insulator 545.

In addition, as illustrated in FIG. 9A and FIG. 9B, the insulator 69 is preferably positioned between the insulator 81 and the oxide 530a, the oxide 530b, the conductor 542a, and the conductor 542b. Furthermore, as illustrated in FIG. 9A and FIG. 9B, the conductor 560 preferably includes a conductor 560a provided inside the insulator 545 and a conductor 560b provided so as to be embedded inside the conductor 560a. Moreover, as illustrated in FIG. 9A and FIG. 9B, the insulator 83 is preferably positioned over the insulator 81, the conductor 560, and the insulator 545.

Note that in this specification and the like, the oxide 530a and the oxide 530b are sometimes collectively referred to as an oxide 530.

Note that the transistor 92 has a structure in which two layers of the oxide 530a and the oxide 530b are stacked in the region where the channel is formed and its vicinity; however, the present invention is not limited thereto. For example, it is possible to employ a structure in which a single layer of the oxide 530b or a stacked-layer structure of three or more layers is provided.

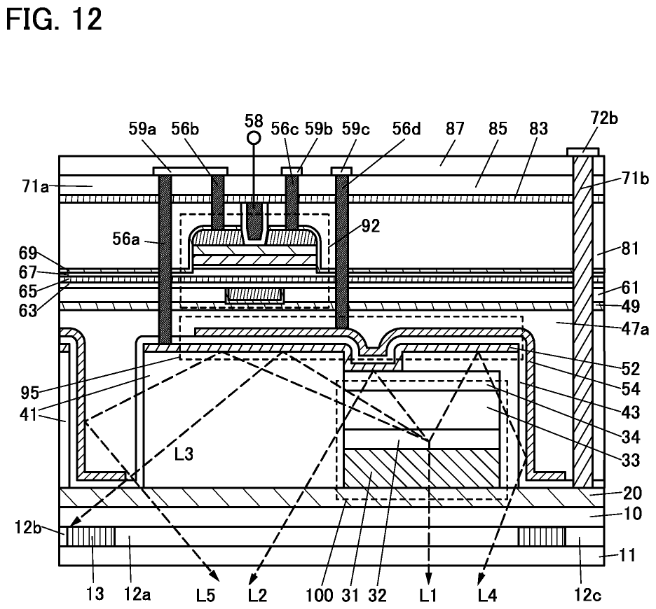

Although the transistor 92 has a structure in which the conductor 560 has a two-layer structure, the present invention is not limited thereto. For example, the conductor 560 may have a single-layer structure or a stacked-layer structure of three or more layers. The transistor 92 illustrated in FIG. 8 and FIG. 12 is just an example and is not limited to the structure illustrated therein, and an appropriate transistor can be used in accordance with a circuit configuration, a driving method, or the like.

Here, the conductor 560 functions as a gate electrode of the transistor, and the conductor 542a and the conductor 542b function as a source electrode and a drain electrode. As described above, the conductor 560 is formed so as to be embedded in the opening of the insulator 81 and the region between the conductor 542a and the conductor 542b. The positions of the conductor 560, the conductor 542a, and the conductor 542b with respect to the opening of the insulator 81 are selected in a self-aligned manner. That is, in the transistor 92, the gate electrode can be positioned between the source electrode and the drain electrode in a self-aligned manner. Therefore, the conductor 560 can be formed without an alignment margin, resulting in a reduction in the area occupied by the transistor 92. Accordingly, miniaturization and high integration of the semiconductor device can be achieved.

In addition, since the conductor 560 is formed in the region between the conductor 542a and the conductor 542b in a self-aligned manner, the conductor 560 does not include a region overlapping with the conductor 542a or the conductor 542b. Thus, parasitic capacitance formed between the conductor 560 and each of the conductor 542a and the conductor 542b can be reduced. As a result, the switching speed of the transistor 92 can be improved, and the transistor 92 can have high frequency characteristics.

The conductor 560 sometimes functions as a first gate (also referred to as top gate) electrode. In addition, the conductor 503 sometimes functions as a second gate (also referred to as bottom gate) electrode. In that case, the threshold voltage of the transistor 92 can be controlled by changing a voltage applied to the conductor 503 independently of a voltage applied to the conductor 560. In particular, the threshold voltage of the transistor 92 can be higher than 0 V and the off-state current can be reduced by applying a negative voltage to the conductor 503. Thus, a drain current at the time when a voltage applied to the conductor 560 is 0 V can be lower in the case where a negative voltage is applied to the conductor 503 than in the case where a negative voltage is not applied to the conductor 503.

The conductor 503 is positioned so as to overlap with the oxide 530 and the conductor 560. Thus, when voltages are applied to the conductor 560 and the conductor 503, an electric field generated from the conductor 560 and an electric field generated from the conductor 503 are connected, so that the channel formation region formed in the oxide 530 can be covered.

In this specification and the like, a transistor structure in which a channel formation region is electrically surrounded by electric fields of a pair of gate electrodes (a first gate electrode and a second gate electrode) is referred to as a surrounded channel (S-channel) structure. Furthermore, in this specification and the like, the surrounded channel (S-channel) structure has a feature that the side surface and the vicinity of the oxide 530 in contact with the conductor 542a and the conductor 542b functioning as the source electrode and the drain electrode are of I-type like the channel formation region. The side surface and the vicinity of the oxide 530 in contact with the conductor 542a and the conductor 542b are in contact with the insulator 69 and thus can be of I-type like the channel formation region. Note that in this specification and the like, “I-type” can be equated with “highly purified intrinsic” to be described later. The S-channel structure disclosed in this specification and the like is different from a Fin-type structure and a planar structure. With the S-channel structure, resistance to a short-channel effect can be enhanced, that is, a transistor in which a short-channel effect is unlikely to occur can be provided.

The conductor 503 has a structure similar to that of the conductor 56; a conductor 503a is formed in contact with an inner wall of an opening in the insulator 49 and the insulator 61, and a conductor 503b is formed on the inner side. Note that the transistor 92 has a structure in which the conductor 503a and the conductor 503b are stacked; however, the present invention is not limited thereto. For example, it is possible to employ a structure in which the conductor 503 has a single layer or a stacked-layer structure of three or more layers. Note that FIG. 8 illustrates an example in which the conductor 56 has a single layer and FIG. 9 illustrates an example in which the conductor 503 has two layers.

Here, for the conductor 503a, it is preferable to use a conductive material that has a function of inhibiting diffusion of impurities such as a hydrogen atom, a hydrogen molecule, a water molecule, and a copper atom (through which the above impurities are unlikely to pass). Alternatively, it is preferable to use a conductive material that has a function of inhibiting diffusion of oxygen (e.g., at least one of an oxygen atom, an oxygen molecule, and the like) (through which the above oxygen is unlikely to pass). Note that in this specification and the like, a function of inhibiting diffusion of impurities or oxygen means a function of inhibiting diffusion of any one or all of the above impurities and the above oxygen.

For example, when the conductor 503a has a function of inhibiting diffusion of oxygen, a reduction in conductivity of the conductor 503b due to oxidation can be inhibited.

In the case where the conductor 503 also functions as a wiring, the conductor 503b is preferably formed using a conductive material that has high conductivity and contains tungsten, copper, or aluminum as its main component. Note that although the conductor 503 is illustrated as a stacked layer of the conductor 503a and the conductor 503b in this embodiment, the conductor 503 may have a single-layer structure.

The insulator 63, the insulator 65, and the insulator 67 each have a function of a second gate insulating film.

Here, for the insulator 67 in contact with the oxide 530, an insulator that contains oxygen more than oxygen in the stoichiometric composition is preferably used. Such oxygen is easily released from the film by heating. In this specification and the like, oxygen released by heating is sometimes referred to as “excess oxygen”. That is, a region containing excess oxygen (also referred to as an “excess-oxygen region”) is preferably formed in the insulator 67. When such an insulator containing excess oxygen is provided in contact with the oxide 530, oxygen vacancies (V_{O}) in the oxide 530 can be reduced and the reliability of the transistor 92 can be improved. When hydrogen enters the oxygen vacancies in the oxide 530, such defects (hereinafter, referred to as VoH in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might reduce the reliability of the transistor. In one embodiment of the present invention, VOH in the oxide 530 is preferably reduced as much as possible so that the oxide 530 becomes a highly purified intrinsic or substantially highly purified intrinsic oxide. It is important to remove impurities such as moisture and hydrogen in an oxide semiconductor (sometimes described as “dehydration” or “dehydrogenation treatment”) and to compensate for oxygen vacancies by supplying oxygen to the oxide semiconductor (sometimes described as “oxygen adding treatment”) in order to obtain an oxide semiconductor whose VOH is sufficiently reduced. When an oxide semiconductor with sufficiently reduced impurities such as VOH is used for a channel formation region of a transistor, stable electrical characteristics can be given.

As the insulator including an excess-oxygen region, specifically, an oxide material from which part of oxygen is released by heating is preferably used. An oxide from which oxygen is released by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of 100° C. to 700° C., or 100° C. to 400° C.

One or more of heat treatment, microwave treatment, and RF treatment may be performed in a state where the insulator including an excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “V_{O}H→V_{O}+H” occurs. Part of hydrogen generated at this time is bonded to oxygen to be H₂O, and removed from the oxide 530 or an insulator near the oxide 530 in some cases. Some hydrogen may be gettered into the conductor 542 in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 92, heat treatment is preferably performed with the surface of the oxide 530 exposed. The heat treatment is performed at higher than or equal to 100° C. and lower than or equal to 450° C., preferably higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (V_{O}). The heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas or inert gas atmosphere.

Note that the oxygen adding treatment performed on the oxide 530 can promote a reaction in which oxygen vacancies in the oxide 530 are filled with supplied oxygen, i.e., a reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In addition, in the case where the insulator 67 includes an excess-oxygen region, it is preferable that the insulator 65 have a function of inhibiting diffusion of oxygen (e.g., an oxygen atom, an oxygen molecule, or the like) (through which oxygen is unlikely to pass).

The insulator 65 preferably has a function of inhibiting diffusion of oxygen or impurities, in which case oxygen contained in the oxide 530 is not diffused into the insulator 63 side. Furthermore, the conductor 503 can be inhibited from reacting with oxygen contained in the insulator 67 or the oxide 530.

For the insulator 65, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current might arise because of a thinner gate insulating film. When a high-k material is used for an insulator functioning as the gate insulating film, a gate voltage during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is unlikely to pass). Aluminum oxide, hafnium oxide, an oxide containing aluminum and hafnium (hafnium aluminate), or the like is preferably used as the insulator containing an oxide of one or both of aluminum and hafnium. In the case where the insulator 65 is formed using such a material, the insulator 65 functions as a layer that inhibits release of oxygen from the oxide 530 and mixing of impurities such as hydrogen from the periphery of the transistor 92 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

In addition, it is preferable that the insulator 63 be thermally stable. For example, silicon oxide and silicon oxynitride are suitable because they are thermally stable. Furthermore, the combination of an insulator that is a high-k material and silicon oxide or silicon oxynitride enables the insulator 63 to have a stacked-layer structure that has thermal stability and a high dielectric constant.

Note that in the transistor 92 in FIG. 9A and FIG. 9B, the insulator 63, the insulator 65, and the insulator 67 are illustrated as the second gate insulating film having a stacked-layer structure of three layers; however, the second gate insulating film may be a single layer or may have a stacked-layer structure of two layers or four or more layers. In such cases, without limitation to a stacked-layer structure formed of the same material, a stacked-layer structure formed of different materials may be employed.

In the transistor 92, a metal oxide functioning as an oxide semiconductor is used as the oxide 530 including a channel formation region. Note that the oxide semiconductor preferably contains at least one of In and Zn. For example, as the oxide 530, a metal oxide such as an In-M-Zn oxide (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor is described in detail in another embodiment.

Furthermore, the metal oxide functioning as the channel formation region in the oxide 530 preferably has a band gap of more than or equal to 2 eV, further preferably more than or equal to 2.5 eV. With the use of a metal oxide having such a wide bandgap, the off-state current of the transistor can be reduced.

When the oxide 530 includes the oxide 530a under the oxide 530b, it is possible to inhibit diffusion of impurities into the oxide 530b from the components formed below the oxide 530a.

Note that the oxide 530 preferably has a stacked-layer structure of a plurality of oxide layers that differ in the atomic ratio of metal atoms. Specifically, the atomic proportion of the element M in the constituent elements in the metal oxide used as the oxide 530a is preferably higher than the atomic proportion of the element M in the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

In addition, the energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To obtain this, the density of defect states in a mixed layer formed at an interface between the oxide 530a and the oxide 530b is preferably made low.

Specifically, when the oxide 530a and the oxide 530b contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 92 can have a high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

Although the conductor 542a and the conductor 542b each having a single-layer structure are illustrated in FIG. 9A and FIG. 9B, they may each have a stacked-layer structure of two or more layers. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material containing indium oxide, tin oxide, or zinc oxide may be used.

In addition, as illustrated in FIG. 9A, a region 543a and a region 543b are sometimes formed as low-resistance regions at an interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier density of the region 543a (the region 543b) increases, and the region 543a (the region 543b) becomes a low-resistance region.

The insulator 69 is provided so as to cover the conductor 542a and the conductor 542b and inhibits oxidation of the conductor 542a and the conductor 542b. At this time, the insulator 69 may be provided so as to cover a side surface of the oxide 530 and so as to be in contact with the insulator 67.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used as the insulator 69. Alternatively, silicon nitride oxide, silicon nitride, or the like can be used as the insulator 69.

It is particularly preferable to use an insulator containing an oxide of one or both of aluminum and hafnium, such as aluminum oxide, hafnium oxide, or an oxide containing aluminum and hafnium (hafnium aluminate), as the insulator 69. In particular, hafnium aluminate has higher heat resistance than a hafnium oxide film. Therefore, hafnium aluminate is preferable because it is less likely to be crystallized by heat treatment in a later step. Note that the insulator 69 is not an essential component when the conductor 542a and the conductor 542b are oxidation-resistant materials or do not significantly lose their conductivity even after absorbing oxygen. Design is appropriately set in consideration of required transistor characteristics.

When the insulator 69 is included, diffusion of impurities such as water and hydrogen contained in the insulator 81 into the oxide 530b through the insulator 545 can be inhibited. Furthermore, oxidation of the conductor 560 due to excess oxygen contained in the insulator 81 can be inhibited.

The insulator 545 functions as a first gate insulating film. Like the insulator 67, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 67, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 into the conductor 560. That is, reduction in the amount of excess oxygen supplied to the oxide 530 can be inhibited. Moreover, oxidation of the conductor 560 due to excess oxygen can be inhibited. For the metal oxide, a material that can be used for the insulator 69 is used.

Note that the insulator 545 may have a stacked-layer structure like the second gate insulating film. As miniaturization and high integration of transistors progress, a problem such as leakage current might arise because of a thinner gate insulating film. For that reason, when the insulator functioning as the gate insulating film has a stacked-layer structure of a high-k material and a thermally stable material, a gate voltage during transistor operation can be reduced while the physical thickness is maintained. Furthermore, the stacked-layer structure can be thermally stable and have a high relative permittivity.

Although the conductor 560 functioning as the first gate electrode has a two-layer structure in FIG. 9A and FIG. 9B, it may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is deposited using a sputtering method, the conductor 560a can have a reduced electrical resistance value to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus is preferably formed using a conductor having high conductivity.

For example, a conductive material containing tungsten, copper, or aluminum as its main component can be used. The conductor 560b may have a stacked-layer structure, for example, a stacked-layer structure of any of the above conductive materials and titanium or titanium nitride.

The insulator 81 is provided over the conductor 542a and the conductor 542b with the insulator 69 therebetween. The insulator 81 preferably includes an excess-oxygen region. For example, the insulator 81 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride are preferable because they are thermally stable. In particular, silicon oxide and porous silicon oxide are preferable because an excess-oxygen region can be easily formed in a later step.

The insulator 81 preferably includes an excess-oxygen region. When the insulator 81 that releases oxygen by heating is provided, oxygen in the insulator 81 can be efficiently supplied to the oxide 530. Note that the concentration of impurities such as water or hydrogen in the insulator 81 is preferably reduced.

The opening of the insulator 81 is formed to overlap with the region between the conductor 542a and the conductor 542b. Accordingly, the conductor 560 is formed so as to be embedded in the opening of the insulator 81 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided so as to be embedded in the opening of the insulator 81; thus, even when the conductor 560 has a shape with a high aspect ratio, the conductor 560 can be formed without collapsing during the process.

The insulator 83 is preferably provided in contact with a top surface of the insulator 81, a top surface of the conductor 560, and a top surface of the insulator 545. When the insulator 83 is deposited using a sputtering method, excess-oxygen regions can be provided in the insulator 545 and the insulator 81. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 83.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 85 functioning as an interlayer film is preferably provided over the insulator 83. As in the insulator 67 or the like, the concentration of impurities such as water or hydrogen in the insulator 85 is preferably reduced.

Furthermore, a conductor 540a and a conductor 540b are positioned in openings formed in the insulator 85, the insulator 83, the insulator 81, and the insulator 69. The conductor 540a and the conductor 540b are provided to face each other with the conductor 560 therebetween.

The insulator 87 is provided over the insulator 85. A substance having a barrier property against oxygen or hydrogen is preferably used for the insulator 87. Therefore, a material similar to that for the insulator 49 can be used for the insulator 87.

In particular, silicon nitride has an excellent blocking effect that prevents the passage of both oxygen and impurities such as hydrogen and moisture that cause a change in electrical characteristics of the transistor. Accordingly, silicon nitride can prevent mixing of impurities such as hydrogen and moisture into the transistor 92 during and after a manufacturing of the transistor. In addition, release of oxygen from the oxide included in the transistor 92 can be inhibited. Therefore, silicon nitride is suitably used for the protective film of the transistor 92.

After the transistor 92 is formed, an opening may be formed so as to surround the transistor 92 and an insulator having a high barrier property against hydrogen or water may be formed so as to cover the opening. Surrounding the transistor 92 with the insulator having a high barrier property can prevent entry of moisture and hydrogen from the outside. Alternatively, a plurality of transistors 92 may be collectively surrounded by the insulator having a high barrier property against hydrogen or water. When an opening is formed so as to surround the transistor 92, for example, the formation of an opening reaching the insulator 65 or the insulator 49 and the formation of the insulator having a high barrier property in contact with the insulator 65 or the insulator 49 are suitable because these formation steps can also serve as part of the manufacturing steps of the transistor 92. Thus, although not illustrated in FIG. 8, the insulator having a high barrier property is preferably formed so as to surround sidewalls of the conductor 56 or the conductor 71. The insulator having a high barrier property against hydrogen or water can be formed using a material similar to that for the insulator 65 or the insulator 49, for example.

With the use of this structure, a semiconductor device using a transistor including an oxide semiconductor can be miniaturized or highly integrated.

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance to the processing temperature in this embodiment may be used. Examples of a glass substrate include a barium borosilicate glass substrate, an aluminosilicate glass substrate, an aluminoborosilicate glass substrate, and a soda lime glass substrate. Alternatively, crystallized glass or the like can be used.

Alternatively, a flexible substrate, an attachment film, paper including a fibrous material, a base film, or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples are polypropylene, polyester, polyvinyl fluoride, and polyvinyl chloride. Other examples are polyamide, polyimide, an aramid resin, an epoxy resin, an inorganic vapor deposition film, and paper. In particular, the use of a semiconductor substrate, a single crystal substrate, an SOI substrate, or the like enables the manufacture of small-sized transistors with a small variation in characteristics, size, shape, or the like and with high current capability. When a circuit is formed with such transistors, lower power consumption of the circuit or higher integration of the circuit can be achieved.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. As the separation layer, a stacked structure of inorganic films, namely a tungsten film and a silicon oxide film, a structure in which an organic resin film of polyimide or the like is formed over a substrate, or a silicon film containing hydrogen can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), or the like), a leather substrate, and a rubber substrate. With the use of any of these substrates, a flexible semiconductor device or a highly durable semiconductor device can be manufactured, high heat resistance can be obtained, or a reduction in weight or thickness can be achieved.

Providing a semiconductor device over a flexible substrate can suppress an increase in weight and can produce a non-breakable semiconductor device.

### Modification Example 1 of Transistor

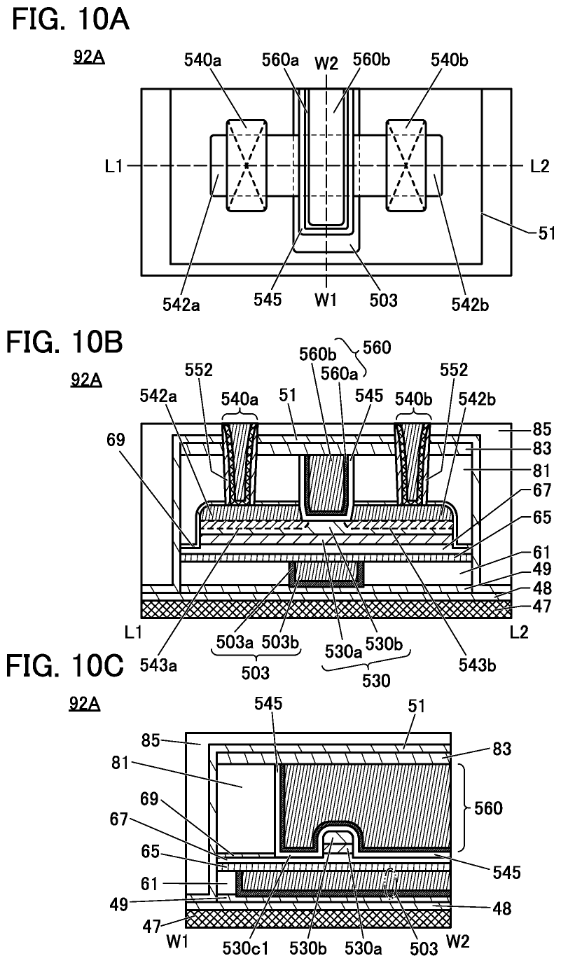

A transistor 92A illustrated in FIG. 10A to FIG. 10C is a modification example of the transistor 92 having the structure illustrated in FIG. 9A and FIG. 9B. FIG. 10B is a cross-sectional view of the transistor 92A in the channel length direction, and FIG. 10C is a cross-sectional view of the transistor 92A in the channel width direction.

The transistor 92A having the structure illustrated in FIG. 10A to FIG. 10C is different from the transistor 92 having the structure illustrated in FIG. 9A and FIG. 9B in that an insulator 552, an insulator 48, and an insulator 51 are included. Furthermore, the transistor 92A is different from the transistor 92 having the structure illustrated in FIG. 9A and FIG. 9B in that the insulator 552 is provided in contact with a side surface of the conductor 540a and a side surface of the conductor 540b. Moreover, the transistor 92A is different from the transistor 92 having the structure illustrated in FIG. 9A and FIG. 9B in that the insulator 63 is not included.

In the transistor 92A having the structure illustrated in FIG. 10A to FIG. 10C, the insulator 48 is provided over the insulator 47. In addition, the insulator 51 is provided over the insulator 83 and the insulator 48.

In the transistor 92A having the structure illustrated in FIG. 10A to FIG. 10C, the insulator 49, the insulator 61, the insulator 65, the insulator 67, the insulator 69, the insulator 81, and the insulator 83 are patterned and covered with the insulator 51. That is, the insulator 51 is in contact with a top surface of the insulator 83, a side surface of the insulator 83, a side surface of the insulator 81, a side surface of the insulator 69, a side surface of the insulator 67, a side surface of the insulator 65, a side surface of the insulator 61, a side surface of the insulator 49, and a top surface of the insulator 48. Thus, the oxide 530 and the like are isolated from the outside by the insulator 51 and the insulator 48.

The insulator 48 and the insulator 51 preferably have high capability of inhibiting diffusion of hydrogen (e.g., at least one of a hydrogen atom, a hydrogen molecule, and the like) or a water molecule. For example, for the insulator 48 and the insulator 51, silicon nitride or silicon nitride oxide that is a material having a high hydrogen barrier property is preferably used. This can inhibit diffusion of hydrogen or the like into the oxide 530, thereby suppressing the degradation of the characteristics of the transistor 92A. Consequently, the reliability of the semiconductor device of one embodiment of the present invention can be increased.

The insulator 552 is provided in contact with the insulator 85, the insulator 51, the insulator 83, the insulator 81, and the insulator 69. The insulator 552 preferably has a function of inhibiting diffusion of hydrogen or water molecules. For example, for the insulator 552, an insulator such as silicon nitride, aluminum oxide, or silicon nitride oxide that is a material having a high hydrogen barrier property is preferably used. In particular, it is preferable to use silicon nitride as the insulator 552 because of its high hydrogen barrier property. The use of a material having a high hydrogen barrier property for the insulator 552 can inhibit diffusion of impurities such as water and hydrogen from the insulator 81 and the like into the oxide 530 through the conductor 540a and the conductor 540b. Furthermore, oxygen contained in the insulator 81 can be inhibited from being absorbed by the conductor 540a and the conductor 540b. As described above, the reliability of the semiconductor device of one embodiment of the present invention can be increased.

### Modification Example 2 of Transistor

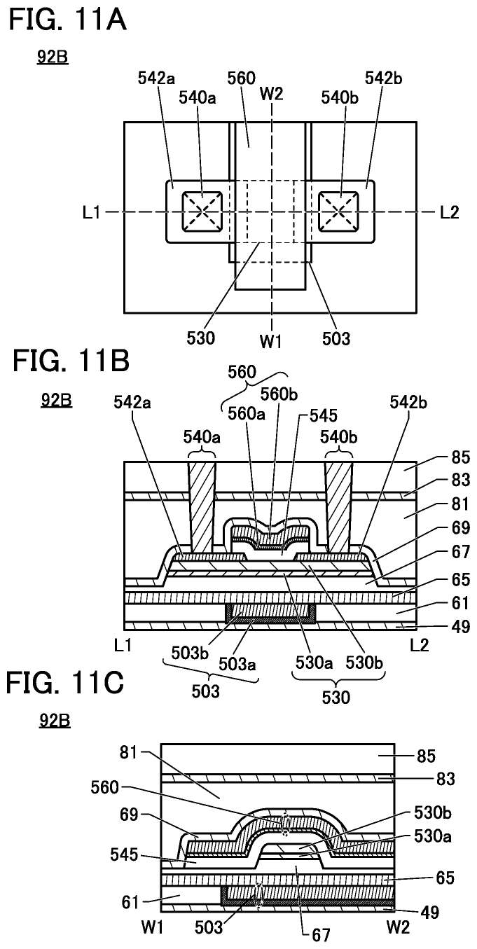

A structure example of a transistor 92B is described with reference to FIG. 11A, FIG. 11B, and FIG. 11C. FIG. 11A is a top view of the transistor 92B. FIG. 11B is a cross-sectional view of a portion indicated by dashed-dotted line L1-L2 in FIG. 11A. FIG. 11C is a cross-sectional view of a portion indicated by dashed-dotted line W1-W2 in FIG. 11A. Note that for clarity of the drawing, some components are not illustrated in the top view of FIG. 11A.

The transistor 92B is a modification example of the transistor 92 and can be replaced with the transistor 92. Accordingly, in order to avoid repeated description, differences of the transistor 92B from the transistor 92 are mainly described.

The conductor 560 functioning as a first gate electrode includes the conductor 560a and the conductor 560b over the conductor 560a. For the conductor 560a, a conductive material that has a function of inhibiting diffusion of impurities such as a hydrogen atom, a hydrogen molecule, a water molecule, and a copper atom is preferably used. Alternatively, it is preferable to use a conductive material having a function of inhibiting diffusion of oxygen (e.g., at least one of an oxygen atom, an oxygen molecule, and the like).

When the conductor 560a has a function of inhibiting diffusion of oxygen, the range of choices for the material of the conductor 560b can be extended. That is, the conductor 560a inhibits oxidation of the conductor 560b, thereby preventing the decrease in conductivity.

The insulator 69 is preferably provided so as to cover the top surface and a side surface of the conductor 560 and a side surface of the insulator 545. For the insulator 69, an insulating material having a function of inhibiting diffusion of oxygen and impurities such as water and hydrogen is preferably used. For example, silicon nitride or the like is preferably used. Moreover, it is possible to use, for example, a metal oxide such as magnesium oxide, gallium oxide, germanium oxide, yttrium oxide, zirconium oxide, lanthanum oxide, neodymium oxide, or tantalum oxide, silicon nitride oxide, or the like.

The insulator 69 can inhibit oxidation of the conductor 560. Moreover, the insulator 69 can inhibit diffusion of impurities such as water and hydrogen contained in the insulator 81 into the transistor 92B.

The transistor 92B has the conductor 560 overlapping part of the conductor 542a and part of the conductor 542b, and thus tends to have larger parasitic capacitance than the transistor 92. Consequently, the transistor 92B tends to have a lower operating frequency than the transistor 92. However, the transistor 92B does not require steps of providing an opening in the insulator 81 and the like and embedding the conductor 560, the insulator 545, and the like in the opening; hence, the productivity of the transistor 92B is higher than that of the transistor 92.

FIG. 12 is a diagram showing a structure example of the display device that is different from that in FIG. 8. Note that in structures of the invention described below, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases.

FIG. 12 is different from FIG. 8 in that part of a side surface of the inorganic light-emitting element 100 is further covered with the conductor 54 functioning as the other electrode of the capacitor 95 with the insulator 41 therebetween. Thus, both electrodes of the capacitor 95 function as reflective electrodes. For example, in the case where an insulator 47a has a light-transmitting property, the light L4 emitted from the inorganic light-emitting element 100 can contribute to display through the substrate 11 because the other electrode of the capacitor 95, which covers part of the side surface of the inorganic light-emitting element 100, functions as a reflective electrode. In addition, the light L5 emitted from the inorganic light-emitting element 100 can contribute to display through the substrate 11 because the other electrode of the capacitor 95, which covers part of the side surface of the inorganic light-emitting element 100 included in an adjacent pixel, functions as a reflective electrode.

The surface where the both electrodes of the capacitor 95 do not face each other can be referred to as the outer side when the side where the both electrodes of the capacitor 95 face each other is the inner side.

The light L2 emitted from the inorganic light-emitting element 100 is reflected by the one electrode of the capacitor 95 and can contribute to display. The light L4 emitted from the inorganic light-emitting element 100 is reflected by the inner side of the other electrode of the capacitor 95 and can contribute to display. The light L5 emitted from the inorganic light-emitting element 100 is reflected by the outer side of the other electrode of the capacitor 95 included in an adjacent pixel and can contribute to display. Accordingly, light emitted from the inorganic light-emitting element 100 can be effectively utilized. In addition, the light L4 and the light L5 are emitted through the display surface of the display device after being reflected by the capacitor 95 functioning as a reflective electrode, thereby effectively increasing the viewing angle.

As another example, the conductor 54 may cover the entire inorganic light-emitting element 100 other than the display surface where light is emitted. When the entire inorganic light-emitting element 100 other than the display surface where light is emitted is covered, light emitted from the inorganic light-emitting element 100 is emitted through the display surface. This increases the outcoupling efficiency of the inorganic light-emitting element 100, and the light reflected by the side surface effectively improves the viewing angle. Furthermore, it is possible to reduce a change in electrical characteristics of the transistor due to light emitted to the transistor.

Note that in FIG. 8, the insulator 47a may have a light-transmitting property or may be a coloring layer. Part of the conductor 54 preferably includes a region overlapping with the insulator 41 and the metal oxynitride film 20.

This embodiment can be combined with the other embodiments and the example as appropriate.

### Embodiment 3

In this embodiment, structure examples of a display device including the inorganic light-emitting element described in any of the above embodiments will be described.

The display device of this embodiment has a function of displaying an image with the use of an inorganic light-emitting element. In this embodiment, in particular, an example where a micro light-emitting diode (hereinafter, also referred to as a micro LED) is used as the inorganic light-emitting element is described.

When a micro LED is used as the display element, the power consumption of the display device can be reduced. Furthermore, the display device can be thinner and more lightweight. Moreover, the display device including the micro LED as the display element has a high contrast and a wide viewing angle; thus, the display quality can be improved.

The area of a light-emitting region of a micro LED is preferably less than or equal to 1 mm², further preferably less than or equal to 10000 μm², still further preferably less than or equal to 3000 μm², even further preferably less than or equal to 700 μm².

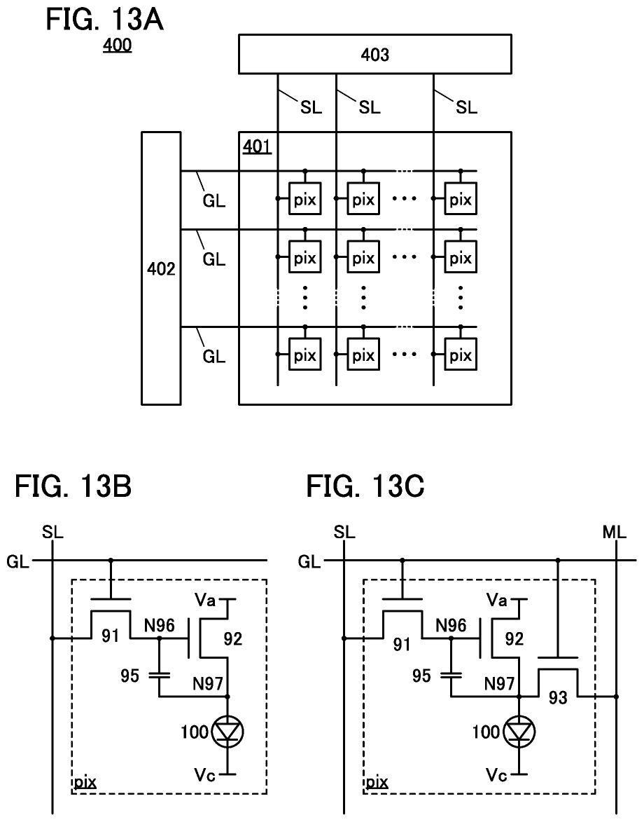

FIG. 13A illustrates a structure example of a display device 400 including an inorganic light-emitting element. The display device 400 includes a pixel unit 401, a driver circuit 402, and a driver circuit 403.

The pixel unit 401 includes a plurality of pixels pix. The pixels pix are connected to wirings SL and wirings GL. The wirings GL are each connected to the driver circuit 402, and the wirings SL are each connected to the driver circuit 403. Selection signals are supplied to the wirings GL, and image signals are supplied to the wirings SL.

The driver circuit 402 has a function of supplying selection signals to the pixels pix. Specifically, the driver circuit 402 has a function of supplying selection signals to the wirings GL, and the wirings GL have a function of transmitting the selection signals output from the driver circuit 402 to the pixels pix. Note that the driver circuit 402 can be referred to as a gate side driver circuit or a gate driver, and the wirings GL can also be referred to as selection signal lines, gate lines, or the like.

The driver circuit 403 has a function of supplying image signals to the pixels pix. Specifically, the driver circuit 403 has a function of supplying image signals to the wirings SL, and the wirings SL have a function of transmitting the image signals output from the driver circuit 403 to the pixels pix. Note that the driver circuit 403 can be referred to as a source side driver circuit or a source driver, and the wirings SL can also be referred to as image signal lines, source lines, or the like.

FIG. 13B illustrates a structure example of the pixel pix including an inorganic light-emitting element as a display element. The pixel pix illustrated in FIG. 13B includes a transistor 91, the transistor 92, the capacitor 95, and the inorganic light-emitting element 100. Note that although the transistor 91 and the transistor 92 are of n-channel type here, the polarities of the transistors can be changed as appropriate. The inorganic light-emitting element described in any of the above embodiments can be used as the light-emitting element 100.

A gate of the transistor 91 is connected to the wiring GL, one of a source and a drain is connected to a gate of the transistor 92 and one electrode of the capacitor 95, and the other of the source and the drain is connected to the wiring SL. One of a source and a drain of the transistor 92 is connected to the other electrode of the capacitor 95 and one electrode of the inorganic light-emitting element 100, and the other of the source and the drain is connected to a wiring to which a potential Va is supplied. The other electrode of the inorganic light-emitting element 100 is connected to a wiring to which a potential Vc is supplied. A node that is connected to the one of the source and the drain of the transistor 91, the gate of the transistor 92, and the one electrode of the capacitor 95 is referred to as a node N96. A node that is connected to the one of the source and the drain of the transistor 92, the other electrode of the capacitor 95, and the one electrode of the light-emitting element 100 is referred to as a node N97.

Here, the case where the potential Va is a high power supply potential and the potential Vc is a low power supply potential is described. The potential Va and the potential Vc can each be a common potential to the plurality of pixels pix. Furthermore, the capacitor 95 functions as a storage capacitor for retaining the potential of the node N96.

The transistor 91 has a function of controlling the supply of the potential of the wiring SL to the node N97. Specifically, the potential of the wiring GL is controlled to turn on the transistor 91, whereby the potential of the wiring SL that corresponds to an image signal is supplied to the node N96 and written to the pixel pix. After that, the potential of the wiring GL is controlled to turn off the transistor 91, whereby the potential of the node N96 is retained.

Then, the amount of current flowing between the source and the drain of the transistor 92 is controlled in accordance with the voltage between the node N96 and the node N97, and the inorganic light-emitting element 100 emits light with a luminance corresponding to the amount of flowing current. Accordingly, the gray level of the pixel pix can be controlled. Note that the transistor 92 preferably operates in a saturation region.

Here, the transistor 91 and the transistor 92 may be provided in the same layer or may be stacked. When the transistor 91 and the transistor 92 are provided in the same layer, the transistor 91 and the transistor 92 can be manufactured at the same time, so that the manufacturing process of the display device can be shortened. On the other hand, when the transistor 91 and the transistor 92 are stacked, the integration degree of the display device can be increased.

As illustrated in FIG. 13B, the pixel pix preferably includes two transistors (91 and 92). Note that one embodiment of the present invention is not limited thereto, and three or more transistors may be provided in the pixel pix.

FIG. 13C illustrates a structure example of the pixel pix including an inorganic light-emitting element as a display element, which is different from that in FIG. 13B. The pixel pix in FIG. 13C includes the transistor 91, the transistor 92, a transistor 93, the capacitor 95, and the inorganic light-emitting element 100. That is, the pixel pix illustrated in FIG. 13C is a pixel in which the transistor 93 for monitoring the amount of current flowing through the transistor 92 is added to the pixel pix illustrated in FIG. 13B.

The gate of the transistor 91 is connected to the wiring GL, one of the source and the drain is connected to the gate of the transistor 92 and one electrode of the capacitor 95, and the other of the source and the drain is connected to the wiring SL. One of the source and the drain of the transistor 92 is connected to the other electrode of the capacitor 95, one electrode of the inorganic light-emitting element 100, and one of a source and a drain of the transistor 93, and the other of the source and the drain is connected to a wiring to which the potential Va is supplied. The other electrode of the inorganic light-emitting element 100 is connected to a wiring to which the potential Vc is supplied. A gate of the transistor 93 is connected to the wiring GL, and the other of the source and the drain is connected to a monitoring line ML. A node that is connected to the one of the source and the drain of the transistor 91, the gate of the transistor 92, and the one electrode of the capacitor 95 is referred to as the node N96. A node that is connected to the one of the source and the drain of the transistor 92, the other electrode of the capacitor 95, the one electrode of the inorganic light-emitting element LE, and the one of the source and the drain of the transistor 93 is referred to as the node N97.

The above-described operation is sequentially performed for every wiring GL, whereby an image for a first frame can be displayed.

Note that the selection of the wirings GL may be performed by either a progressive method or an interlaced method. In addition, the supply of image signals to the wirings SL may be performed by dot sequential driving in which image signals are sequentially supplied to the wirings SL, or may be performed by line sequential driving in which image signals are concurrently supplied to all the wirings SL. Alternatively, the image signals may be sequentially supplied to every set of wirings SL.

Next, in a second frame period, an image is displayed by an operation similar to that in the first frame period. Thus, the image displayed on the pixel unit 401 is rewritten.

As a semiconductor used for the transistors included in the pixels pix, a Group 14 element such as silicon or germanium, a compound semiconductor such as gallium arsenide, an organic semiconductor, a metal oxide, or the like can be used. The semiconductor may be a non-single-crystal semiconductor (e.g., an amorphous semiconductor, a microcrystalline semiconductor, or a polycrystalline semiconductor) or a single crystal semiconductor.

The transistors included in the pixels pix preferably contain an amorphous semiconductor, in particular, hydrogenated amorphous silicon (a-Si:H) in channel formation regions. Transistors using an amorphous semiconductor easily deal with the increase in substrate area; thus, for example, when a large-screen display device that is compatible with 4K2K broadcasting or 8K4K broadcasting is manufactured, the manufacturing process can be simplified.

Furthermore, a transistor including a metal oxide in a channel formation region (an OS transistor) can be used as each of the transistors included in the pixels pix. An OS transistor has higher field-effect mobility than a transistor including hydrogenated amorphous silicon. In addition, an OS transistor does not require a crystallization process that has been necessary for a transistor using polycrystalline silicon or the like.

Since an OS transistor has an extremely low off-state current, in the case where an OS transistor is used as the transistor 91, an image signal can be retained in the pixel pix for an extremely long period. This enables the update frequency of an image signal to be extremely low in a period when there is no change in the image displayed on the pixel unit 401 or a period when the change is at a certain level or lower. The update frequency of an image signal can be set less than or equal to once every 0.1 seconds, less than or equal to once every second, or less than or equal to once every 10 seconds, for example. In particular, when a large number of pixels pix are provided to be compatible with 4K2K broadcasting, 8K4K broadcasting, or the like, reducing the power consumption by skipping update of an image signal is effective.

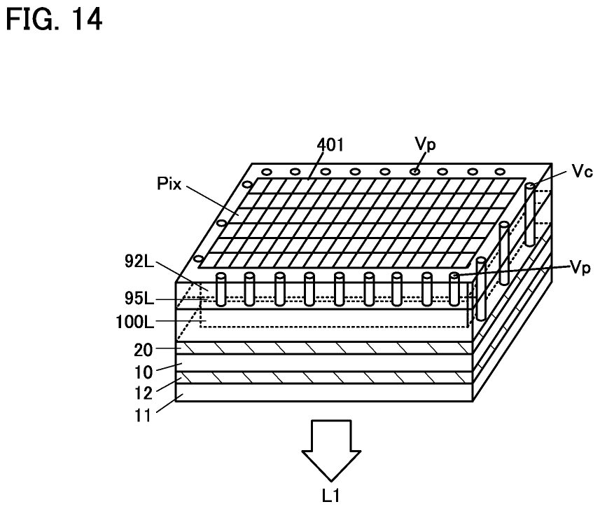

FIG. 14 is a diagram showing a display device. The display device includes the substrate 10, the substrate 11, the functional layer 12, the metal oxynitride film 20, the pixel unit 401, a plurality of terminals Vp, and a plurality of terminals Vc. The pixel unit 401 includes a plurality of pixels Pix. The metal oxynitride film 20 functions as a common electrode, and the plurality of pixels Pix are formed over the common electrode. Note that the common electrode is preferably supplied with a cathode potential.

The plurality of terminals Vp are terminals for supplying signals to the respective pixels Pix. Note that some of the terminals Vp are connected to the wiring SL and the other terminals VP are connected to the wiring GL. The plurality of terminals Vc are connected to the metal oxynitride film 20 functioning as the common electrode. Note that since the plurality of terminals Vc are provided, the cathode potential of the inorganic light-emitting element 100 included in each pixel Pix can be inhibited from floating due to the influence of a resistance component included in the metal oxynitride film 20.

The display device further includes an inorganic light-emitting element formation layer 100L where the inorganic light-emitting element 100 is formed; a capacitor formation layer 95L where the capacitor 95 is formed; and a transistor formation layer 92L where the transistor 92 is formed. The pixel Pix includes the inorganic light-emitting element 100 formed in the inorganic light-emitting element formation layer 100L; the capacitor 95 formed in the capacitor formation layer 95L; and the transistor 92 formed in the transistor formation layer 92L. The terminal Vp is electrically connected to a wiring in the transistor formation layer.

Note that bumps can be provided over the terminal Vp and the terminal Vc. Although not illustrated in FIG. 14, the driver circuit 402 and the driver circuit 403 are preferably attached to each other. Accordingly, a small-sized and high-resolution display device can be obtained. When the driver circuit 402 and the driver circuit 403 are attached to each other through the bumps, the number of components can be reduced. The aforementioned display device can be used in a head mounted display (HMD), and is preferably used in a goggle-type display device, a glasses-type display device, or the like, for example.

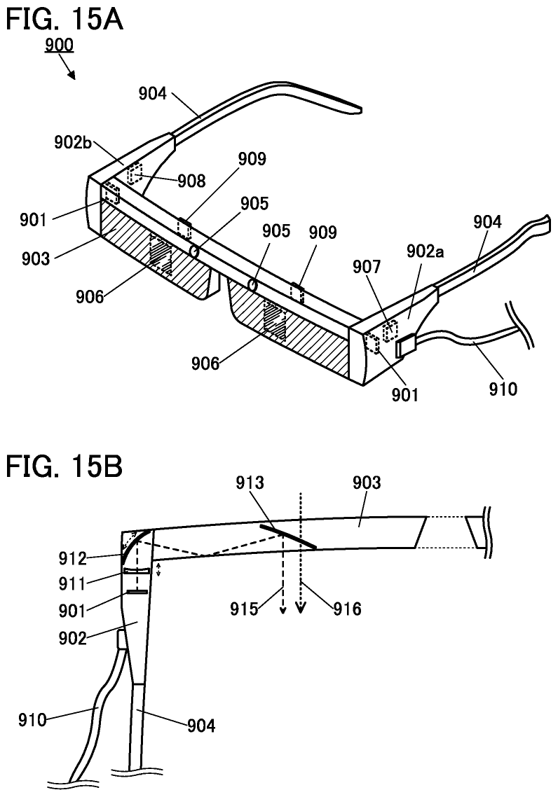

FIG. 15A is a perspective view of a glasses-type information terminal 900. The information terminal 900 includes a pair of display panels 901, a pair of housings (a housing 902a and a housing 902b), a pair of optical members 903, a pair of mounting portions 904, and the like.

The information terminal 900 can project an image displayed on the display panel 901 onto a display region 906 of the optical member 903. Since the optical members 903 have a light-transmitting property, a user can see images displayed on the display regions 906, which are superimposed on transmission images seen through the optical members 903. Thus, the information terminal 900 is an information terminal capable of AR display or VR display. Note that the display portion 14 described in the above embodiment can include not only the display panel 901 but also the optical members 903 including the display regions 906 and an optical system including a lens 911, a reflective plate 912, and a reflective plane 913 to be described later. A micro LED display is preferably used as the display panel 901. An organic EL display, an inorganic EL display, a liquid crystal display, or the like can be used as the display panel 901. Note that in the case where a liquid crystal display is used as the display panel 901, the inorganic light-emitting element 100 can be used a light source that functions as a backlight.

In addition, a pair of cameras 905 capable of taking front images and a pair of cameras 909 capable of taking images on the user side are provided in the information terminal 900. The cameras 905 are parts of components of a camera module, and the cameras 909 are parts of components of the camera module. A plurality of cameras 905 are preferably provided in the information terminal 900 because three-dimensional images of a material or a cooking device can be taken. However, the cameras 905 in this embodiment are not limited thereto. One camera 905 may be provided in the information terminal 900. In that case, the camera 905 may be provided in a center portion of a front of the information terminal 900 or may be provided in a front of one of the housing 902a and the housing 902b. Furthermore, two cameras 905 may be provided in fronts of the housing 902a and the housing 902b.

The camera 909 can sense the user's gaze. Thus, two cameras 909 for a right eye and for a left eye are preferably provided. Note that in the case where one camera can sense the gaze of both eyes, one camera 909 may be provided. In addition, the camera 909 may be an infrared camera capable of detecting infrared rays.

The housing 902a includes a wireless communication device 907, and a video signal or the like can be supplied to a housing 902. Furthermore, the wireless communication device 907 preferably includes a communication module and communicates with a database. Note that instead of the wireless communication device 907 or in addition to the wireless communication device 907, a connector that can be connected to a cable 910 for supplying a video signal or a power supply potential may be provided. The cable 910 may have a function of the wiring 10c that is connected to the housing 10b. When the housing 902 is provided with an acceleration sensor, a gyroscope sensor, or the like, the orientation of the user's head can be sensed and an image corresponding to the orientation can also be displayed on the display region 906. Moreover, the housing 902 is preferably provided with a battery, in which case charging can be performed with or without a wire. Note that the battery is preferably incorporated in the pair of mounting portions 904.

Furthermore, the housing 902b is provided with an integrated circuit 908. The integrated circuit 908 includes a controller, a processor, a memory, an audio controller, and the like, which are not illustrated in FIG. 15, and the information terminal 900 includes the camera 905, the wireless communication device 907, the pair of display panels 901, a microphone, a speaker, and the like. The information terminal 900 preferably has a function of controlling the various components, a function of generating images, and the like. The integrated circuit 908 preferably has a function of generating synthesized images for AR display or VR display.

Data communication with an external device can be performed by the wireless communication device 907. For example, when data transmitted from the outside is output to the integrated circuit 908, the integrated circuit 908 can generate image data for AR display or VR display on the basis of the data. Examples of the data transmitted from the outside include data obtained by transmitting an image acquired by the camera 905 to a database, and analyzing the image in the database.

Next, a method for projecting an image on the display region 906 of the information terminal 900 is described using FIG. 15B. The display panel 901, the lens 911, and the reflective plate 912 are provided in the housing 902. In addition, the reflective plane 913 functioning as a half mirror is provided in a portion corresponding to the display region 906 of the optical member 903.

Light 915 emitted from the display panel 901 passes through the lens 911 and is reflected by the reflective plate 912 to the optical member 903 side. In the optical member 903, the light 915 is fully reflected repeatedly by end surfaces of the optical member 903 and reaches the reflective plane 913, so that an image is projected on the reflective plane 913. Accordingly, the user can see both the light 915 reflected by the reflective plane 913 and transmitted light 916 that has passed through the optical member 903 (including the reflective plane 913).

FIG. 15B illustrates an example in which the reflective plate 912 and the reflective plane 913 each have a curved surface. This can increase optical design flexibility and reduce the thickness of the optical member 903, compared to the case where they have flat surfaces. Note that the reflective plate 912 and the reflective plane 913 may have flat surfaces.

A component having a mirror surface can be used for the reflective plate 912, and the reflective plate 912 preferably has high reflectance. As the reflective plane 913, a half mirror utilizing reflection of a metal film may be used, but the use of a prism utilizing total reflection or the like can increase the transmittance of the transmitted light 916.

Here, the housing 902 preferably includes a mechanism for adjusting the distance and angle between the lens 911 and the display panel 901. This enables focus adjustment, zooming in/out of an image, or the like. One or both of the lens 911 and the display panel 901 are configured to be movable in the optical-axis direction, for example.

In addition, the housing 902 preferably includes a mechanism capable of adjusting the angle of the reflective plate 912. The position of the display region 906 where images are displayed can be changed by changing the angle of the reflective plate 912. Thus, the display region 906 can be placed at an optimal position in accordance with the position of the user's eye.

The display device of one embodiment of the present invention can be used for the display panel 901. Thus, the information terminal 900 can perform display with extremely high resolution.

This embodiment can be combined with the other embodiments and the example as appropriate.

### Embodiment 4

In this embodiment, electronic devices of one embodiment of the present invention that include the display device described in any of the above embodiments will be described with reference to drawings.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

The electronic device of one embodiment of the present invention may include an antenna. When a signal is received by the antenna, the electronic device can display an image, information, or the like on a display unit. Note that since the display unit can be formed using the display device, the display unit can also be referred to as a display device. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radioactive rays, flow rate, humidity, gradient, oscillation, a smell, or infrared rays).

The electronic device of one embodiment of the present invention can have a variety of functions. For example, it can have a function of displaying a variety of information (a still image, a moving image, a text image, and the like) on the display unit, a touch panel function, a function of displaying a calendar, date, time, and the like, a function of executing a variety of software (programs), a wireless communication function, and a function of reading out a program or data stored in a recording medium.

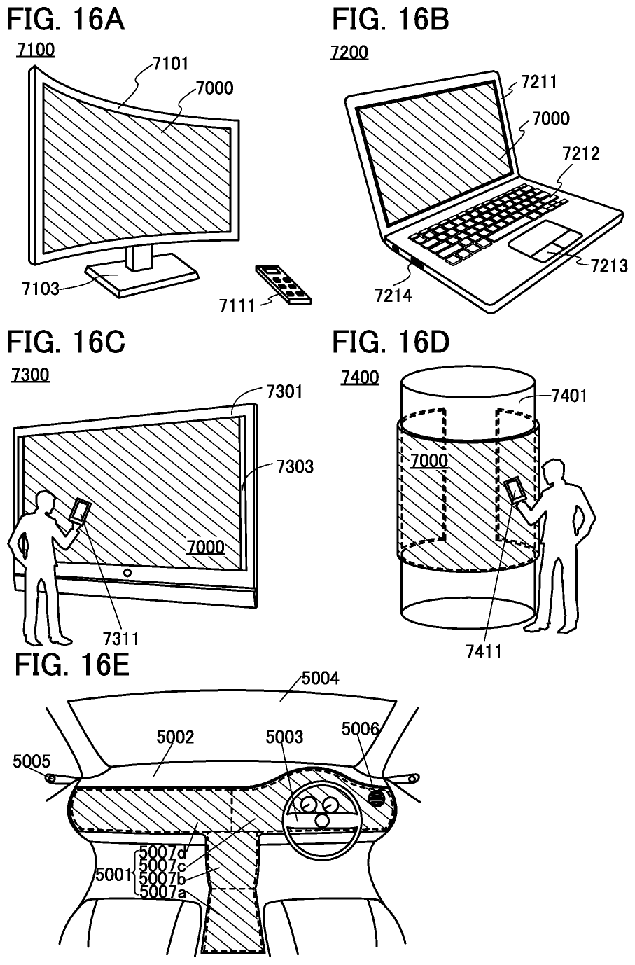

FIG. 16A illustrates an example of a television device. In a television device 7100, a display unit 7000 is incorporated in a housing 7101. Here, a structure in which the housing 7101 is supported by a stand 7103 is illustrated.

The display device of one embodiment of the present invention can be used in the display unit 7000.

The television device 7100 illustrated in FIG. 16A can be operated with an operation switch provided in the housing 7101 or a separate remote controller 7111. Alternatively, the display unit 7000 may include a touch sensor, and the television device 7100 can be operated by touch on the display unit 7000 with a finger, a stylus, or the like. The remote controller 7111 may be provided with a display unit for displaying information output from the remote controller 7111. With operation keys or a touch panel provided in the remote controller 7111, channels and volume can be operated and images displayed on the display unit 7000 can be operated.

Note that the television device 7100 is provided with a receiver, a modem, and the like. A general television broadcast can be received with the receiver. Furthermore, when the television device is connected to a communication network with or without wires via the modem, one-way (from a transmitter to a receiver) or two-way (between a transmitter and a receiver or between receivers, for example) data communication can be performed.

FIG. 16B illustrates a laptop personal computer 7200. The laptop personal computer 7200 includes a housing 7211, a keyboard 7212, a pointing device 7213, an external connection port 7214, and the like. In the housing 7211, the display unit 7000 is incorporated.

The display device of one embodiment of the present invention can be used as the display unit 7000.

FIG. 16C and FIG. 16D illustrate examples of digital signage.

Digital signage 7300 illustrated in FIG. 16C includes a housing 7301, the display unit 7000, a speaker 7303, and the like. Furthermore, the digital signage can include an LED lamp, operation keys (including a power switch or an operation switch), a connection terminal, a variety of sensors, a microphone, and the like.

In addition, FIG. 16D is digital signage 7400 attached to a cylindrical pillar 7401. The digital signage 7400 includes the display unit 7000 provided along a curved surface of the pillar 7401.

The display device of one embodiment of the present invention can be used in the display unit 7000 in FIG. 16C and FIG. 16D.

A larger area of the display unit 7000 can increase the amount of information that can be provided at a time. In addition, the larger display unit 7000 attracts more attention, so that the effectiveness of the advertisement can be increased, for example.

It is preferable to use a touch panel for the display unit 7000 because not only an image or a moving image is displayed on the display unit 7000 but also users can operate intuitively. Moreover, for an application for providing information such as route information or traffic information, usability can be enhanced by intuitive operation.

Furthermore, as illustrated in FIG. 16C and FIG. 16D, it is preferable that the digital signage 7300 or the digital signage 7400 work with an information terminal 7311 or an information terminal 7411 such as a user's smartphone through wireless communication. For example, information of an advertisement displayed on the display unit 7000 can be displayed on a screen of the information terminal 7311 or the information terminal 7411. Moreover, by operation of the information terminal 7311 or the information terminal 7411, display on the display unit 7000 can be switched.

Furthermore, it is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

The display device of one embodiment of the present invention can be incorporated along a curved surface of an inside wall or an outside wall of a house or a building or the interior or the exterior of a vehicle. FIG. 16E illustrates an example of installation of the display device of one embodiment of the present invention in a vehicle.

FIG. 16E illustrates a structure example of a vehicle equipped with a display unit 5001. As the display unit 5001, the display device of one embodiment of the present invention can be used. Note that in the example illustrated in FIG. 16E, the display unit 5001 is installed in, but not limited to, a right-hand drive vehicle; installation in a left-hand drive vehicle is also possible. In that case, the left and right of the arrangement illustrated in FIG. 16E are reversed.

FIG. 16E illustrates a dashboard 5002, a steering wheel 5003, a windshield 5004, and the like that are arranged around a driver's seat and a front passenger's seat. The display unit 5001 is placed in a predetermined position in the dashboard 5002, specifically, around the driver, and has a rough T shape. Although one display unit 5001 formed of a plurality of display panels 5007 (display panels 5007a, 5007b, 5007c, and 5007d) is provided along the dashboard 5002 in the example illustrated in FIG. 16E, the display unit 5001 may be divided and placed in a plurality of places.

Note that the plurality of display panels 5007 may have flexibility. In this case, the display unit 5001 can be processed into a complicated shape; for example, a structure in which the display unit 5001 is provided along a curved surface of the dashboard 5002 or the like or a structure in which a display region of the display unit 5001 is not provided at a connection portion of the steering wheel, display units of meters, a ventilation duct 5006, or the like can easily be achieved.

In addition, a plurality of cameras 5005 that take pictures of the situations at the rear side may be provided outside the vehicle. Although the camera 5005 is provided instead of a side mirror in the example in FIG. 16E, both the side mirror and the camera may be provided.

As the camera 5005, a CCD camera, a CMOS camera, or the like can be used. In addition, an infrared camera may be used in combination with such a camera. The infrared camera, which has a higher output level with a higher temperature of an object, can detect or extract a living body such as a human or an animal.

An image captured with the camera 5005 can be output to any one or more of the display panels 5007. This display unit 5001 is mainly used for supporting driving of the vehicle. An image of the situation on the rear side is taken at a wide angle of view by the camera 5005, and the image is displayed on the display panels 5007 so that the driver can see a blind area for avoiding an accident.

Furthermore, a distance image sensor may be provided over a roof of the vehicle, for example, and an image obtained by the distance image sensor may be displayed on the display unit 5001. For the distance image sensor, an image sensor, LIDAR (Light Detection and Ranging), or the like can be used. An image obtained by the image sensor and the image obtained by the distance image sensor are displayed on the display unit 5001, whereby more information can be provided to the driver to support driving.

The display unit 5001 may also have a function of displaying map information, traffic information, television images, DVD images, and the like. For example, map information can be displayed on the display panels 5007a, 5007b, 5007c, and 5007d as a large display screen. Note that the number of display panels 5007 can be increased depending on the image to be displayed.

The images displayed on the display panels 5007a, 5007b, 5007c, and 5007d can be freely set to meet the driver's preference. For example, television images or DVD images are displayed on the display panel 5007d on the left, map information is displayed on the display panel 5007b at the center position, meters are displayed on the display panel 5007c on the right, and audio information and the like are displayed on the display panel 5007a near a transmission gear (between the driver's seat and the front passenger's seat). In addition, a combination of the plurality of display panels 5007 can add a fail-safe function to the display unit 5001. For example, even when any one of the display panels 5007 is broken for any reason, a display region can be changed so that display can be performed using another display panel 5007.

This embodiment can be combined with the other embodiments and the example as appropriate.

### Example

In this example, evaluation results of the crystallinity and orientation of a metal nitride film formed over a metal oxynitride film by the method described in any of the above embodiments will be described. Specifically, a plurality of samples (Sample 1 to Sample 5) in each of which a metal oxynitride film was deposited on a substrate by the method described in any of the above embodiments were prepared, and each sample was subjected to Out-of-plane measurement and p scanning using X rays. For each of Sample 1 and Sample 2, a metal oxynitride film was formed over a substrate and a metal nitride film was formed over the metal oxynitride film. For Sample 3, a metal oxide film was formed over a substrate and a metal nitride film was formed over the metal oxide film. For each of Sample 4 and Sample 5, which are comparative samples of Sample 1 to Sample 3, a metal nitride film was formed over a substrate.

### <Method for Manufacturing Samples>

First, a method for manufacturing Sample 1 to Sample 3 will be described. Note that Sample 4 and Sample 5 were manufactured as comparative samples of Sample 1 to Sample 3.

Sample 1 to Sample 3 were manufactured by the method for manufacturing a metal oxynitride film described as an example in Embodiment 1. Specifically, a single crystal substrate was prepared, and a metal oxynitride film was deposited on the substrate by a sputtering method using an oxide target with a gas introduced into a reaction chamber. Note that before the metal oxynitride film is deposited on the substrate, pretreatment such as air annealing or vacuum annealing at high temperatures is not performed on the substrate. In addition, heat treatment is not performed on the deposited metal oxynitride film.

As the deposition conditions of the metal oxynitride film common to Sample 1 to Sample 3, the deposition pressure was set to 0.4 Pa, the deposition power was set to 200 W, and the distance between the oxide target and the substrate was set to 130 mm.

The single crystal substrates used in manufacture of the samples are described. As the single crystal substrate, an a-plane sapphire substrate was prepared for Sample 1, and yttria-stabilized zirconia (YSZ) substrates were prepared for Sample 2 and Sample 3. The plane orientation of the a-plane sapphire substrate is (110) and the plane orientation of the YSZ substrate is (111). Note that in this example, it is confirmed that the metal oxynitride film and indium tin oxide function as buffer layers even when substrates with different plane orientations are used.

Next, the oxide targets used for manufacture of the samples are described. In—Ga—Zn oxide targets with In:Ga:Zn=4:2:4.1 [atomic ratio] were used as the oxide targets for Sample 1 and Sample 2. Thus, the metal oxynitride films of Sample 1 and Sample 2 are In—Ga—Zn oxynitride films (denoted as IGZON). For Sample 3, indium tin oxide was used as the oxide target.

Next, the gas introduced into the reaction chamber (also referred to as a deposition gas) is described. A nitrogen gas (N₂) at 45 sccm was used as the deposition gas for Sample 1 and Sample 2. A mixed gas of an oxygen gas (O₂) at 5 sccm and an argon gas (Ar) at 40 sccm was used as the deposition gas for Sample 3.

As the deposition conditions of the metal nitride film common to Sample 1 to Sample 3, the deposition pressure was set to 0.4 Pa, the deposition power was set to 200 W, and the distance between the nitride target and the substrate was set to 130 mm. Note that the metal oxynitride film is deposited on the substrate in each of Sample 1 and Sample 2, and the metal oxynitride film is an In—Ga—Zn oxynitride film. For Sample 3, the metal oxide film is deposited on the substrate and the metal oxide film is an indium tin oxide film.

Next, the nitride target used for manufacture of the samples is described. As the nitride target, a sintered GaN target was used for Sample 1 to Sample 3.

Next, the gas introduced into the reaction chamber (also referred to as a deposition gas) is described. A nitrogen gas (N₂) at 45 sccm was used as the deposition gas for Sample 1 to Sample 3.

Note that pretreatment and heat treatment after the deposition are not performed on Sample 1 to Sample 3.

Next, substrate temperatures during deposition of the metal oxynitride film are described. The substrate temperatures for Sample 1 to Sample 3 were set to 200° C.

Next, substrate temperatures during deposition of the metal nitride film are described. The substrate temperatures for Sample 1 to Sample 3 were set to 300° C.

Sample 1 to Sample 3 were manufactured as described above. Table 1 and Table 2 summarize the processing conditions of the samples. Table 1 shows the processing conditions for manufacture of the metal oxynitride film and Table 2 shows the processing conditions for manufacture of the metal nitride film. Note that for Sample 4, the metal nitride film was formed over the a-plane sapphire substrate, and for Sample 5, the metal nitride film was formed over the yttria-stabilized zirconia (YSZ) substrate.

TABLE 1

| | | | | Substrate |
|---|---|---|---|---|
| Sample | Single crystal substrate | Oxide target | Gas flow rate | temperature |
| 1 | a-plane sapphire | In—Ga—Zn oxide | N2 = 45 sccm | 200° C. |
| | substrate | (In:Ga:Zn = | | |
| 2 | YSZ substrate | 4:2:4.1[atomic | | |
| | | ratio]) | | |
| 3 | | Indium tin oxide | O2 = 5 sccm, | |
| | | | Ar = 40 sccm | |

TABLE 2

| | | | | | Substrate |
|---|---|---|---|---|---|
| Sample | Single crystal substrate | Substrate surface | Nitride target | Gas flow rate | temperature |
| 1 | a-plane sapphire substrate | In—Ga—Zn | Sintered GaN | N2 = 45 sccm | 300° C. |
| 2 | YSZ substrate | oxynitride | | | |
| 3 | | Indium tin oxide | | | |
| 4 | a-plane sapphire substrate | — | | | |
| 5 | YSZ substrate | — | | | |

Out-of-plane measurement, ϕ scanning, and the like using X rays were performed on each of Sample 1 to Sample 5 that were manufactured. An X-ray diffraction apparatus, D8 DOSCOVER, manufactured by Bruker Japan K.K. was used as an apparatus for X-ray measurement; and a zero-dimensional detector was used as a detector. In this example, the results of Out-of-plane measurement and ϕ scanning are shown in the drawing.

Note that in each graph showing the ϕ scanning results, the horizontal axis represents the angle ϕ [°] (denoted as phi (deg.)), and the vertical axis represents the peak intensity (denoted as Intensity (a.u.)). In order to evaluate the in-plane orientation, the full width at half maximum of a measured peak was obtained.

As the result of ϕ scanning on each sample, in this example, six diffraction peaks were measured in each sample. Thus, it was found that the crystal structure of the metal nitride formed over the metal oxynitride was a wurtzite structure in Sample 1 to Sample 3.

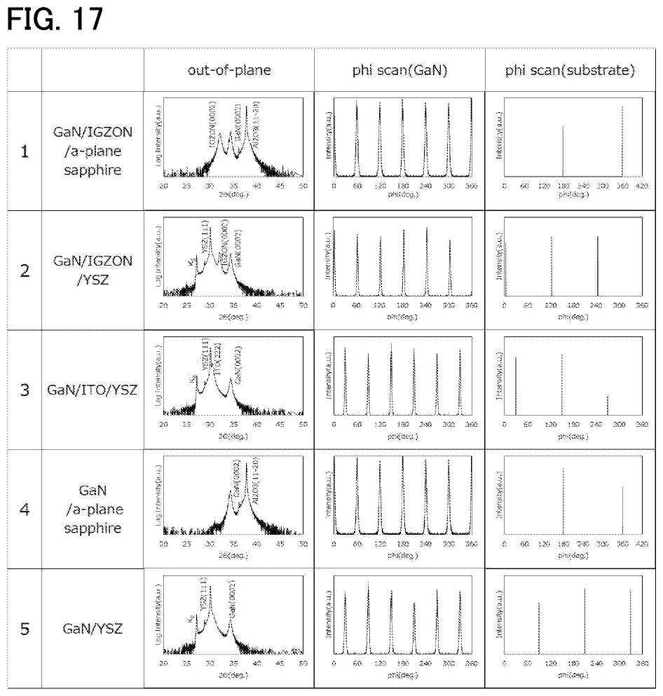

In this example, FIG. 17 shows the Out-of-plane measurement results, the ϕ scanning results (denoted as phi scan (GaN)), and the ϕ scanning results (denoted as phi scan (substrate)) of the substrates used for manufacture of the samples. Table 3 shows the results of measurement of full widths at half maximum (FWHM) from the ϕ scanning results of Sample 1 to Sample 5. Note that omitted is the description on the Out-of-plane measurement results and the ϕ scanning results of the substrates used for manufacture of the samples

TABLE 3

| | | | | Full width at half |
|---|---|---|---|---|
| Sample | Single crystal substrate | Buffer layer | Substrate surface | maximum (FWHM) |
| 1 | a-plane sapphire substrate | In—Ga—Zn | GaN | 5.250 |
| 2 | YSZ substrate | oxynitride | | 2.960 |
| 3 | | Indium tin oxide | | 3.360 |
| 4 | a-plane sapphire substrate | — | | 4.277 |
| 5 | YSZ substrate | — | | 4.350 |

Next, the evaluation results of Sample 1 to Sample 3 will be described in detail.

### <Evaluation of Sample 1>

FIG. 17 shows the measurement results of Sample 1. For Sample 1, an In—Ga—Zn oxynitride film was formed over an a-plane sapphire substrate and a metal nitride film (GaN) was further formed over the In—Ga—Zn oxynitride film.

As the result of scanning on Sample 1, six diffraction peaks were observed. Note that Sample 4 was manufactured as a comparative sample. For Sample 4, a metal nitride film (GaN) was formed over an a-plane sapphire substrate. Sample 1 and Sample 4 each have six diffraction peaks observed and are found to have six-fold symmetry.

In other words, the (101) plane of the metal nitride film (GaN) of Sample 1 has six-fold symmetry, showing that the metal nitride film (GaN) of Sample 1 has in-plane orientation. In addition, since an angle formed by the (002) plane and the (101) plane of the wurtzite structure is approximately 62°, the peak having six-fold symmetry obtained by ϕ scanning at this angle indicates that the crystal included in the metal nitride film (GaN) of Sample 1 has a wurtzite structure. Thus, it is found that the metal nitride film (GaN) of Sample 1 is a c-axis epitaxial film.

The above shows that the metal nitride film of Sample 1 has a wurtzite structure and is epitaxially grown. Note that the full width at half maximum (FWHM) of a diffraction peak of Sample 1 measured by ϕ scanning was 5.25. Hence, the In—Ga—Zn oxynitride film is suitable for a buffer layer that grows the metal nitride film (GaN).

### <Evaluation of Sample 2>

FIG. 17 shows the measurement results of Sample 2. For Sample 2, an In—Ga—Zn oxynitride film was formed over an yttria-stabilized zirconia (YSZ) substrate and a metal nitride film (GaN) was further formed over the In—Ga—Zn oxynitride film.

As the result of ϕ scanning on Sample 2, six diffraction peaks were observed. Note that Sample 5 was manufactured as a comparative sample. For Sample 5, a metal nitride film (GaN) was formed over an yttria-stabilized zirconia (YSZ) substrate. Sample 2 and Sample 5 each have six diffraction peaks observed and are found to have a wurtzite structure.

In other words, the (101) plane of the metal nitride film (GaN) of Sample 2 has six-fold symmetry, showing that the metal nitride film (GaN) of Sample 2 has in-plane orientation. In addition, since an angle formed by the (002) plane and the (101) plane of the wurtzite structure is approximately 62°, the peak having six-fold symmetry obtained by ϕ scanning at this angle indicates that the crystal included in the metal nitride film (GaN) of Sample 2 has a wurtzite structure. Thus, it is found that the metal nitride film (GaN) of Sample 2 is a c-axis epitaxial film.

The above shows that the metal nitride film of Sample 2 has a wurtzite structure and is epitaxially grown. Note that the full width at half maximum of a diffraction peak of Sample 2 measured by ϕ scanning was 2.96. Hence, the In—Ga—Zn oxynitride film is suitable for a buffer layer that grows the metal nitride film (GaN).

### <Evaluation of Sample 3>

FIG. 17 shows the measurement results of Sample 3. For Sample 3, an indium tin oxide (ITO) film was formed over an yttria-stabilized zirconia (YSZ) substrate and a metal nitride film (GaN) was further formed over the indium tin oxide (ITO) film.

As the result of ϕ scanning on Sample 3, six diffraction peaks were observed, showing that a wurtzite structure was obtained.

In other words, the (101) plane of the metal nitride film (GaN) of Sample 3 has six-fold symmetry, showing that the metal nitride film (GaN) of Sample 3 has in-plane orientation. In addition, since an angle formed by the (002) plane and the (101) plane of the wurtzite structure is approximately 62°, the peak having six-fold symmetry obtained by ϕ scanning at this angle indicates that the crystal included in the metal nitride film (GaN) of Sample 3 has a wurtzite structure. Thus, it is found that the metal nitride film (GaN) of Sample 3 is a c-axis epitaxial film.

The above shows that the metal nitride film (GaN) of Sample 3 has a wurtzite structure and is epitaxially grown. Note that the full width at half maximum of a diffraction peak of Sample 3 measured by ϕ scanning was 3.36. Hence, the In—Ga—Zn oxynitride film is suitable for a buffer layer that grows the metal nitride film (GaN).

Hall effect measurement was performed to obtain the carrier concentrations of the metal oxynitride film and the metal oxide film used in Sample 1 to Sample 3. Table 4 shows the evaluation results of the Hall effect measurement. As an example of a Hall effect measurement equipment, the specific resistance/Hall measurement system, ResiTest 8310 (manufactured by TOYO Corporation), can be given. With the specific resistance/Hall measurement system ResiTest 8310, the direction and strength of a magnetic field are changed in a certain cycle and in synchronization therewith, only a Hall electromotive voltage caused in a sample is detected, so that AC (alternate current) Hall measurement can be performed; thus, even in the case of a material with low mobility and high resistivity, a Hall electromotive voltage can be detected.

For an evaluation sample, a metal oxynitride film was formed over an yttria-stabilized zirconia (YSZ) substrate under the conditions shown in Table 1. Table 3 shows the results of the Hall effect measurement of the evaluation sample. As comparative samples, an indium tin oxide (ITO) film and an In—Ga—Zn oxynitride film, each of which was formed over an yttria-stabilized zirconia (YSZ) substrate were measured. Note that the indium tin oxide (ITO) film is usually used as a transparent conductive film in a display device and a lighting device.

TABLE 4

| | IGZON/YSZ | ITO/YSZ | |
|---|---|---|---|
| | 200° C. | 200° C. | Unit |
| Carrier concentration | 1.12E+20 | 2.06E+19 | [1/cm³] |
| Hall mobility | 9.77 | 10.10 | [cm²/V*s] |
| Resistivity | 5.69E−03 | 5.92E−03 | [Ωcm] |

The Hall effect measurement results indicate that the In—Ga—Zn oxynitride film functions as a conductive film equivalent to the indium tin oxide (ITO) film. In addition, in Sample 2, which includes the metal nitride film (GaN) formed over the In—Ga—Zn oxynitride film, the metal nitride film (GaN) having higher crystallinity than that in Sample 5 was found to be obtained. This means that the In—Ga—Zn oxynitride film functions as a buffer layer for forming the metal nitride film (GaN). Furthermore, the In—Ga—Zn oxynitride film, which has conductivity equivalent to that of the indium tin oxide (ITO), can have a function of an electrode of an inorganic light-emitting element.

Note that the In—Ga—Zn oxynitride film can be formed by sputtering and the metal nitride film (GaN) can be further formed over the In—Ga—Zn oxynitride film by a sputtering method. With a sputtering apparatus including a plurality of sputtering targets, the In—Ga—Zn oxynitride film and the metal nitride film (GaN) can be formed successively. In addition, the In—Ga—Zn oxynitride film and the metal nitride film (GaN) can be formed at low temperatures.

At least parts of the structure, the method, and the like shown in this example can be implemented in appropriate combination with other embodiments described in this specification.

### REFERENCE NUMERALS

: 10: substrate, 11: substrate, 12: functional layer, 12a: functional layer, 12b: functional layer, 12c: functional layer, 13: light-shielding layer, 14: display unit, 20: metal oxynitride film, 20a: crystal, 30: metal nitride film, 30a: crystal, 31: clad layer, 32: active layer, 33: clad layer, 34: conductor, 35: electrode, 36: electrode, 41: insulator, 43: insulator, 47: insulator, 47a: insulator, 48: insulator, 49: insulator, 51: insulator, 52: conductor, 54: conductor, 54a: magnet unit, 56: conductor, 56a: conductor, 56d: conductor, 58: terminal, 59: conductor, 59a: conductor, 59d: conductor, 61: insulator, 63: insulator, 65: insulator, 67: insulator, 69: insulator, 71: conductor, 71a: conductor, 71b: conductor, 72: conductor, 72a: conductor, 72b: conductor, 81: insulator, 83: insulator, 85: insulator, 87: insulator, 91: transistor, 92: transistor, 92A: transistor, 92B: transistor, 92L: transistor formation layer, 93: transistor, 95: capacitor, 95L: capacitor formation layer, 100: inorganic light-emitting element, 100L: inorganic light-emitting element formation layer, 101: reciprocal lattice point, 111: reciprocal lattice point, 200: sputtering apparatus, 201: deposition chamber, 202: substrate holder, 203: substrate, 204: sputtering target, 205: backing plate, 206: magnet unit, 206a: magnet unit, 206b: magnet unit, 207a: oscillation range, 207b: oscillation range, 400: display device, 401: pixel unit, 402: driver circuit, 403: driver circuit, 503: conductor, 503a: conductor, 503b: conductor, 518: conductor, 530: oxide, 530a: oxide, 530b: oxide, 540a: conductor, 540b: conductor, 542: conductor, 542a: conductor, 542b: conductor, 543a: region, 543b: region, 545: insulator, 552: insulator, 560: conductor, 560a: conductor, 560b: conductor, 900: information terminal, 901: display panel, 902: housing, 902a: housing, 902b: housing, 903: optical member, 904: mounting portion, 905: camera, 906: display region, 907: wireless communication device, 908: integrated circuit, 909: camera, 910: cable, 911: lens, 912: reflective plate, 913: reflective plane, 915: light, 916: transmitted light, 5001: display unit, 5002: dashboard, 5003: steering wheel, 5004: windshield, 5005: camera, 5006: ventilation duct, 5007: display panel, 5007a: display panel, 5007b: display panel, 5007c: display panel, 5007d: display panel, 7000: display unit, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal

1. An inorganic light-emitting element comprising:
a first film comprising indium and oxygen; and
a second film comprising gallium and nitrogen,
wherein the second film has a wurtzite structure, and
wherein the first film is one electrode of the inorganic light-emitting element.

2. The inorganic light-emitting element according to claim 1,
wherein the first film comprises indium, oxygen, gallium, zinc, and nitrogen.

3. A semiconductor device comprising:
an inorganic light-emitting element comprising:
a first film comprising indium and oxygen; and
a second film comprising gallium and nitrogen;
a transistor; and
a capacitor,
wherein the second film has a wurtzite structure,
wherein one electrode of the capacitor is formed above the second film,
wherein the transistor is formed above the other electrode of the capacitor,
wherein the one electrode of the capacitor is configured to reflect light emitted from the inorganic light-emitting element, and
wherein the inorganic light-emitting element emits light through the first film.

4. The semiconductor device according to claim 3,
wherein the transistor comprises a metal oxide in a semiconductor layer.

5. The semiconductor device according to claim 4,
wherein the semiconductor layer of the transistor comprises indium, gallium, zinc, and oxygen.

6. A method for manufacturing an inorganic light-emitting element comprising a first film and a second film over a substrate, the method comprising:
a first step of forming the first film by a sputtering method using an oxide target comprising zinc and having conductivity; and
a second step of forming the second film over the first film by a sputtering method using a nitride target comprising gallium and nitrogen and having conductivity,
wherein in the first step, the first film is deposited while a temperature of the substrate is higher than or equal to 80° C. and lower than or equal to 500° C., and a flow rate of a nitrogen gas is higher than or equal to 50% and lower than or equal to 100% of a total flow rate of the gas, and
wherein in the second step, the second film is deposited while a temperature of the substrate is higher than or equal to 80° C. and lower than or equal to 500° C., and a flow rate of a nitrogen gas is higher than or equal to 80% and lower than or equal to 100% of a total flow rate of the gas.

7. The method for manufacturing the inorganic light-emitting element according to claim 6,
wherein the oxide target comprises indium and gallium.

8. The method for manufacturing the inorganic light-emitting element according to claim 6,
wherein the substrate is a single crystal yttria-stabilized zirconia substrate, and
wherein a plane orientation of the substrate is (111).

9. The method for manufacturing the inorganic light-emitting element according to claim 6,
wherein the substrate is a single crystal sapphire substrate, and
wherein a plane orientation of the substrate is (110).
